(19) United States
(12) Patent Application Publication
(10) Pub. No.: US 2023/0250311 A1
(43) Pub. Date: Aug. 10, 2023

(54) METHOD FOR PRODUCING COMPOSITION FOR FORMING INTERLAYER FOR NANOIMPRINT, METHOD FOR PRODUCING LAMINATE, IMPRINT PATTERN PRODUCING METHOD, AND METHOD FOR MANUFACTURING DEVICE

(71) Applicant: FUJIFILM Corporation, Tokyo (JP)

(72) Inventors: Naoya SHIMOJU, Haibara-gun (JP); Akihiro HAKAMATA, Haibara-gun (JP)

(73) Assignee: FUJIFILM Corporation, Tokyo (JP)

(21) Appl. No.: 18/188,026

(22) Filed: Mar. 22, 2023

Related U.S. Application Data
(63) Continuation of application No. PCT/JP2021/034786, filed on Sep. 22, 2021.

(30) Foreign Application Priority Data
Sep. 28, 2020 (JP) 2020-162083

(51) Int. Cl. C09D 133/14; H01L 21/027; B29C 59/02

(52) U.S. Cl. CPC C09D 133/14; H01L 21/0271; B29C 59/022; B29C 59/026

(57) ABSTRACT

Provided are a method for producing a composition for forming an interlayer for nanoimprint, the method including a filtering step of filtering a precursor composition 1 including a resin having a polymerizable group with a filter, a step of adding a solvent to the precursor composition 1 after the step to obtain a precursor composition 2, and a filtering step of filtering the precursor composition 2 with a filter, in which a proportion of a total solid content of the obtained composition is 0.1% to 1.0% by mass; a method for producing a laminate formed of the composition for forming an interlayer; an imprint pattern producing method using the composition for forming an interlayer; and a method for manufacturing a device, which includes the imprint pattern producing method.

### CROSS-REFERENCE TO RELATED APPLICATIONS

This application is a Continuation of PCT International Application No. PCT/JP2021/034786 filed on Sep. 22, 2021, which claims priority under 35 U.S.C § 119(a) to Japanese Patent Application No. 2020-162083 filed on Sep. 28, 2020. Each of the above application(s) is hereby expressly incorporated by reference, in its entirety, into the present application.

### BACKGROUND OF THE INVENTION

### 1. Field of the Invention

The present invention relates to a method for producing a composition for forming an interlayer for nanoimprint, a method for producing a laminate, an imprint pattern producing method, and a method for manufacturing a device.

### 2. Description of the Related Art

An imprinting method is a technique in which a fine pattern is transferred to a material by pressing a metal mold (generally also called a mold or a stamper) on which a pattern is formed. The imprinting method enables simple and precise production of a fine pattern, and thus is expected to be applied in various fields, such as a precision processing field for semiconductor integrated circuits, in recent years. In particular, a nanoimprint technique for forming a fine pattern of a nano-order level is attracting attention.

JP2009-282080A discloses a method for producing a resist resin-containing solution, including a filtration step of filtering a resist resin-containing solution through a filter, in which the filtration step includes a first filtration step and a second filtration step having a lower linear speed than the first filtration step.

WO2006/121162A discloses a method for producing a radiation-sensitive resin composition, including a step of providing a filter apparatus equipped with a filter composed of a polyamide-based resin filter and a polyethylene-based resin filter connected in series, circulating a precursor composition for the radiation-sensitive resin composition in the filter apparatus so that the precursor composition passes through the filter a plurality of times, so that foreign substance in the precursor composition is removed.

### SUMMARY OF THE INVENTION

As the imprinting method, methods called a thermal imprinting method and a curable imprinting method have been proposed depending on a transfer method. In the thermal imprinting method, for example, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. In this method, various materials can be selected, but there are problems in that it is difficult to form a fine pattern, such as the need for high pressure during pressing and the deterioration of dimensional accuracy due to heat contraction.

In the curable imprinting method, for example, while the mold is pressed against a curable layer formed of a composition for forming a pattern, the curable layer is cured by light, heat, or the like, and then the mold is released. Since it is imprinted on an uncured substance, it is possible to omit part or all of high-pressure addition and high-temperature heating, and it is possible to easily produce a fine pattern. Moreover, since a dimensional change before and after curing is small, there is also an advantage that a fine pattern can be formed with high accuracy.

Recently, new developments such as a nanocasting method in which the advantages of both the thermal imprinting method and the curable imprinting method are combined, and a reversal imprinting method for producing a three-dimensional laminated structure have also been reported.

Examples of the curable imprinting method include a method in which a curable layer is formed by applying, by a coating or the like, a composition for forming a pattern onto a member to be applied, which is selected from the group consisting of a base material (subjected to an adhesion treatment such as forming an interlayer as necessary) and a mold, and then a member which is not selected as the member to be applied from the group consisting of the base material and the mold is brought into contact with the curable layer as a contact member. For example, the curable layer is cured by light irradiation or the like in a state in which the above-described contact member and the above-described curable layer are in contact with each other, and then the mold is released to produce a cured substance to which a desired pattern is transferred.

In such an imprinting method, since it is necessary to release the mold from the composition for forming a pattern while leaving the composition for forming a pattern on the base material, sufficient adhesiveness between the base material and the composition for forming a pattern may be required.

Therefore, the composition for forming an interlayer for nanoimprint is used to form an interlayer between the base material and the curable layer.

As described above, in a case where the interlayer is formed between the base material and the curable layer, there is room for further improvement in adhesiveness between the base material, the interlayer, and the curable layer.

An object of the present invention is to provide a method for producing a composition for forming an interlayer for nanoimprint, with which an interlayer having excellent adhesiveness between a base material, an interlayer, and a curable layer can be formed, a method for producing a laminate formed of the composition for forming an interlayer for nanoimprint, an imprint pattern producing method using the laminate, and a method for manufacturing a device, which includes the imprint pattern producing method.

Typical embodiments of the present invention are shown below.

<1> A method for producing a composition for forming an interlayer for nanoimprint, which is used for forming an interlayer existing between a base material and a curable layer, the method comprising:

a first filtering step of filtering a precursor composition 1 including a resin having a polymerizable group with a filter;

a preparing step of adding a solvent to the precursor composition 1 after the first filtering step to obtain a precursor composition 2; and

a second filtering step of filtering the precursor composition 2 with a filter,

in which a proportion of a total solid content of the obtained composition for forming an interlayer for nanoimprint to a total mass of the obtained composition for forming an interlayer for nanoimprint is 0.1% to 1.0% by mass.

<2> The method for producing a composition for forming an interlayer for nanoimprint according to <1>,

in which a concentration of solid contents of the precursor composition 1 subjected to the first filtering step is greater than 1.0% by mass, and

a concentration of solid contents of the precursor composition 2 subjected to the second filtering step is 1.0% by mass or lower.

<3> The method for producing a composition for forming an interlayer for nanoimprint according to <1> or <2>,

in which a pore diameter of the filter used in the second filtering step is smaller than a pore diameter of the filter used in the first filtering step.

<4> The method for producing a composition for forming an interlayer for nanoimprint according to any one of <1> to <3>,

in which a filtration speed in a case where the precursor composition 1 passes through the filter in the first filtering step is 1.0 to 100.0 cm/min.

<5> The method for producing a composition for forming an interlayer for nanoimprint according to any one of <1> to <4>,

in which at least one filter used in the second filtering step is polyethylene, polypropylene, nylon, or polytetrafluoroethylene.

<6> The method for producing a composition for forming an interlayer for nanoimprint according to any one of <1> to <5>,

in which a content of a polymerization inhibitor is 0.01 mass or lower with respect to the total mass of the composition for forming an interlayer for nanoimprint.

<7> A method for producing a laminate, the method comprising:

a step of applying, onto a base material, the composition for forming an interlayer for nanoimprint, which is obtained by the method for producing a composition for forming an interlayer for nanoimprint according to any one of <1> to <6>.

<8> An imprint pattern producing method comprising:

a curable layer-forming step of applying a composition for forming a pattern onto a member to be applied, which is selected from the group consisting of a laminate obtained by the method for producing a laminate according to <7> and a mold;

a contact step of contacting a member which is not selected as the member to be applied from the group consisting of the laminate and the mold with the composition for forming a pattern as a contact member;

a curing step of forming the composition for forming a pattern into a cured substance; and

a peeling step of peeling off the mold from the cured substance.

<9> A method for manufacturing a device, comprising:

the imprint pattern producing method according to <8>.

According to the present invention, a method for producing a composition for forming an interlayer for nanoimprint, with which an interlayer having excellent adhesiveness between a base material, an interlayer, and a curable layer can be formed, a method for producing a laminate formed of the composition for forming an interlayer for nanoimprint, an imprint pattern producing method using the laminate, and a method for manufacturing a device, which includes the imprint pattern producing method, are provided.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step can be achieved.

In the present specification, with regard to a group (atomic group), in a case where the group (atomic group) is described without specifying whether the group (atomic group) is substituted or unsubstituted, the description means that the group (atomic group) includes both a group (atomic group) having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group).

In the present specification, unless otherwise specified, “exposure” is meant to include not only drawing using light but also drawing using particle rays such as electron beams and ion beams. Examples of energy rays used for the drawing include actinic rays such as a bright line spectrum of a mercury lamp, far ultraviolet rays typified by an excimer laser, extreme ultraviolet rays (EUV light), and X-rays, and particle rays such as electron beams and ion beams.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the present specification, a solid content in a composition means components other than a solvent, and a content (concentration) of the solid content in the composition is represented by the mass percentage of the components other than the solvent with respect to the total mass of the composition, unless otherwise specified.

In the present specification, a temperature is 23° C., an atmospheric pressure is 101,325 Pa (1 atm), and a relative humidity is 50% RH, unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified. The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ3000, and TSKgel Super HZ2000 (manufactured by TOSOH CORPORATION). Moreover, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. Moreover, unless otherwise specified, in a case where a direction in which layers are stacked on a substrate is referred to as “upward” or there is a photosensitive layer, a direction from the substrate to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

In the present specification, “imprint” preferably refers to transfer of a pattern with a size of 1 nm to 10 mm, and more preferably refers to transfer (nanoimprint) of a pattern with a size of about 10 nm to 100 μm.

(Method for Producing Composition for Forming Interlayer for Nanoimprint)

The method for producing a composition for forming an interlayer for nanoimprint (hereinafter, also simply referred to as a “composition for forming an interlayer”) according to the embodiment of the present invention is a method for producing a composition for forming an interlayer for nanoimprint, which is used for forming an interlayer existing between a base material and a curable layer, the method including: a first filtering step of filtering a precursor composition 1 including a resin having a polymerizable group with a filter; a preparing step of adding a solvent to the precursor composition 1 after the first filtering step to obtain a precursor composition 2; and a second filtering step of filtering the precursor composition 2 with a filter, in which a proportion of a total solid content of the obtained composition for forming an interlayer for nanoimprint to a total mass of the obtained composition for forming an interlayer for nanoimprint is 0.1% to 1.0% by mass.

According to the method for producing a composition for forming an interlayer for nanoimprint of the present invention, a composition for forming an interlayer for nanoimprint, with which an interlayer having excellent adhesiveness between a base material, an interlayer, and a curable layer can be formed, is obtained.

The mechanism for obtaining the above-described effect is not clear, but is presumed as follows.

In the related art, in producing the composition for forming an interlayer for nanoimprint, after preparing a precursor composition by mixing components included in the composition for forming an interlayer for nanoimprint, a filter treatment is performed for the purpose of removing foreign substance.

Here, the above-described precursor composition is, for example, a composition which includes a resin having a polymerizable group and has a very low concentration of solid contents (for example, a solid content of 1.0% by mass or lower, and the like) to form a thin film.

The present inventors have found that, in a case where such a composition having a low concentration of solid contents is filtered, the foreign substance (for example, foreign substance which is easily deformed by pressure, such as gel-like foreign substance) may pass through the filter.

Since the above-described interlayer is a thin film (for example, 40 nm or lower), in a case where the composition for forming an interlayer includes foreign substance, it is considered that adhesiveness is lowered even in a case where the foreign substance is fine foreign substance.

The present inventors have found that, by producing the composition for forming an interlayer for nanoimprint by first performing a filtration treatment (first filtering step) on a precursor composition 1 having a high concentration of solid contents of the composition, adding a solvent to the precursor composition 1 after the first filtering step, preparing a precursor composition 2 in which the concentration of solid contents is lowered, and than performing again a filtration treatment (second filtering step) on the precursor composition 2, the number of foreign substances included in the composition for forming an interlayer for nanoimprint is reduced.

Since the number of foreign substances included in the composition for forming an interlayer for nanoimprint, obtained by such an operation, is small, it is considered that it is possible to form an interlayer having excellent adhesiveness between the base material, the interlayer, and the curable layer.

Moreover, during storage of the composition, since polymerization of the resin having a polymerizable group, or the like proceeds with the foreign substance as a nucleus, it has been found that the adhesiveness is lowered in a case where the interlayer is formed of the composition after the storage.

In the method for producing a composition for forming an interlayer for nanoimprint according to the embodiment of the present invention, it is considered that, in a case where the precursor composition 1 after the first filtration is stored, generation of the foreign substance due to the above-described progress of polymerization or the like is suppressed, so that the adhesiveness is excellent even in a case where the above-described composition after the storage is subjected to the subsequent preparing step and second filtering step. It is presumed that this is because the foreign substance is easily removed by the first filtering step performed in a state in which the concentration of solid contents is high.

In addition, since the generation of the foreign substance due to the progress of polymerization or the like is suppressed in this way, in some cases, it is possible to adopt a design that reduces a content of a polymerization inhibitor included in the composition. In such an aspect, it is considered that, since polymerizable property of the resin or the like in curing is improved, the adhesiveness is further improved.

Furthermore, according to the method for producing a composition for forming an interlayer for nanoimprint of the present invention, since a composition for forming an interlayer for nanoimprint, in which the number of foreign substances is reduced, is obtained, it is presumed that damage to a mold is also suppressed.

Hereinafter, details of each step in the method for producing a composition for forming an interlayer for nanoimprint according to the embodiment of the present invention will be described.

<Interlayer>

The method for producing a composition for forming an interlayer for nanoimprint according to the embodiment of the present invention is a method for producing a composition for forming an interlayer for nanoimprint, which is used for forming an interlayer existing between a base material and a curable layer.

It is preferable that the above-described interlayer and the base material are in direct contact with each other.

In addition, it is preferable that the above-described interlayer and the curable layer are in direct contact with each other.

The above-described interlayer is preferably a closely adhesive film for an imprint lithography. The closely adhesive film for an imprint lithography refers to a closely adhesive film formed between the curable layer and the base material, which is used for an imprint lithography.

A method for forming the interlayer and the curable layer is not particularly limited, and examples thereof include a method in which a composition for forming an interlayer for nanoimprint is applied in a layered manner onto a base material, at least a part of a solvent in the composition for forming an interlayer for nanoimprint is removed to form an interlayer, and then a curable layer is formed on the interlayer.

Examples of the method for forming the interlayer and the method for forming the curable layer each include a method for producing a laminate described later, and an curable layer-forming step or a contact step in an imprint pattern forming method described later.

<First Filtering Step>

The method for producing a composition for forming an interlayer for nanoimprint according to the embodiment of the present invention includes a first filtering step of filtering a precursor composition 1 including a resin having a polymerizable group with a filter.

In the first filtering step, the precursor composition 1 may pass through the filter one or more times, or may pass through two or more times. In a case where the precursor composition 1 passes through the filter two or more times, the respective filters may be the same, or the material, the filtration surface area, the thickness, the pore diameter, and the like thereof may be different from each other. The foreign substance may be efficiently removed by passing the precursor composition through the filter two or more times.

A method for passing the precursor composition 1 through the filter two or more times is not particularly limited, but preferred examples thereof include a method of circulating the composition in a device including the filters, a method of passing through a plurality of filters connected in series one or more times each, a method of re-filtering with the same or a different filter after filtration with a certain filter, and a method of combining these methods.

[Precursor Composition 1]

The precursor composition 1 refers to a composition including a plurality of components included in the composition for forming an interlayer for nanoimprint, and is preferably a composition including all components included in the composition for forming an interlayer for nanoimprint.

The precursor composition 1 preferably includes a resin and a polymerization inhibitor.

Moreover, a proportion (concentration of solid contents) of the total solid content of the precursor composition 1 to the total mass of the precursor composition 1 is preferably 1% to 50% by mass and more preferably 20% to 40% by mass.

The precursor composition 1 is prepared, for example, by a precursor composition 1 preparation step described later.

[Speed of Passing Through Filter]

A speed at which the precursor composition 1 passes through the filter in the first filtering step is not particularly limited, but is preferably 1.0 to 100.0 cm/min and more preferably 5.0 to 50.0 cm/min.

Here, the speed at which the precursor composition 1 passes through the filter (hereinafter, also simply referred to as a “filtration speed”) is a value calculated by the following expression (1).

Expression (1): Filtration speed (cm/min)=Filtration flow rate (cm³/min)/Filtration surface area of filtration filter film (cm²)

As the filtration surface area (cm²) of the filtration filter film, typically, a value published by the manufacturer of the filtration filter film can be adopted.

The filtration flow rate (cm³/min) is calculated by measuring the amount of the composition which has passed through the filter.

[Effective Filtration Area]

An effective filtration area of the filter in the first filtering step is preferably 300 cm² or greater, more preferably 500 cm² or greater, and still more preferably 1,000 cm² or greater. The upper limit thereof is not particularly limited, and for example, may be 50,000 cm² or lower.

A filtration pressure (applied pressure) in the first filtering step may vary depending on the material of the filter and the filtration device, the chemical structure of components included in the precursor composition 1, and the like, but it is preferably 0.5 MPa or lower, more preferably 0.3 MPa or lower, still more preferably 0.2 MPa or lower, and particularly preferably 0.1 MPa or lower. By setting such a range, it is possible to more effectively suppress particles of impurities from passing through the filter.

The lower limit of the above-described filtration pressure is not particularly limited, but is preferably 0.05 MPa or greater.

In the present invention, an average flow rate of the precursor composition 1 is preferably 20 cm³ or greater per minute, and more preferably 100 cm³ to 3000 cm³ per minute.

Among the filters used in the first filtering step, it is preferable that a pore diameter of at least one of the filters is 50 μm or lower, and it is more preferable that the pore diameters of all filters are 10 μm or lower.

The pore diameter is more preferably 8 μm or lower, and still more preferably 1 μm to 6 μm. By passing the precursor composition 1 through the filter having the above-described pore diameter, the foreign substance can be efficiently removed.

A material of the filter used in the first filtering step is not particularly specified, but a cellulose-based resin, a polypropylene-based resin, a fluorine-based resin, a polyethylene-based resin, a nylon-based resin, a glass fiber, or the like can be preferably used.

In particular, it is preferable that at least one type of the filters used in the first filtering step is a cellulose-based resin or a glass fiber.

Examples of the filter used in the first filtering step include a membrane filter and a depth filter, and a known filter can be used without particular limitation, but a membrane filter is preferable.

By using the membrane filter, it is possible to prevent gel-like impurities and the like from passing through the filter while being deformed in the filter.

Moreover, it is preferable that at least one type of the filter used in the first filtering step is a filter cartridge obtained by processing the membrane filter into a pleated shape. The filter cartridge processed into a pleated shape has an advantage in that the effective filtration area can be produced.

A temperature of the precursor composition 1 in the first filtering step may or may not be adjusted.

For example, the temperature of the precursor composition 1 may be set in a range of 10° C. to 40° C. for the filtration, and the temperature thereof is also preferably set to 15° C. to 30° C.

<Precursor Composition 1 Preparation Step>

The method for producing a composition for forming an interlayer for nanoimprint according to the embodiment of the present invention may include a step (also referred to as a “precursor composition 1 preparation step”) of preparing the precursor composition 1.

The step of preparing the precursor composition 1 is preferably a step of mixing each component included in the composition for forming an interlayer for nanoimprint.

The mixing method is not particularly limited, and a known method may be used. The mixing is carried out, for example, in a range of 0° C. to 100° C., preferably in a range of 10° C. to 40° C.

<Preparing Step>

The method for producing a composition for forming an interlayer for nanoimprint according to the embodiment of the present invention includes a preparing step of adding a solvent to the precursor composition 1 after the above-described first filtering step to prepare a precursor composition 2.

The solvent in the preparing step is not particularly limited, and examples thereof include a solvent included in the composition for forming an interlayer for nanoimprint, which will be described later.

Moreover, it is also preferable that the solvent added in the preparing step is the solvent included in the precursor composition 1.

In a case where the precursor composition 1 includes a plurality kinds of solvents, it is preferable that the solvent added in the preparing step also includes the same plurality kinds of solvents as those in the precursor composition 1, and it is preferable that the same plurality kinds of solvents as those in the precursor composition 1 are included in the same content ratio as the precursor composition 1.

A proportion (concentration of solid contents) of the total solid content of the precursor composition 2 prepared in the preparing step to the total mass of the precursor composition 2 is preferably 0.1% to 1.0% by mass.

The above-described concentration of solid contents is more preferably 0.8% by mass or lower, and still more preferably 0.6% by mass or lower. Moreover, the lower limit value thereof is preferably 0.1% by mass or greater, more preferably 0.15% by mass or greater, and still more preferably 0.2% by mass or greater.

In the preparing step, components other than the solvent may be further added to the precursor composition 1, but a step of adding only the solvent is also one of preferred aspects of the present invention.

Moreover, in the preparing step, adding a polymerization initiator to the precursor composition together with the solvent is also one of preferred aspects of the present invention.

The preparation step is carried out, for example, in a range of 0° C. to 100° C., preferably in a range of 10° C. to 40° C.

<Second Filtering Step>

The method for producing a composition for forming an interlayer for nanoimprint according to the embodiment of the present invention includes a second filtering step of filtering the precursor composition 2 with a filter.

In the second filtering step, the precursor composition 2 may pass through the filter one or more times, or may pass through two or more times. In a case where the precursor composition 2 passes through the filter two or more times, the respective filters may be the same, or the material, the filtration surface area, the thickness, the pore diameter, and the like thereof may be different from each other. The foreign substance may be efficiently removed by passing the precursor composition through the filter two or more times.

A method for passing the precursor composition 2 through the filter two or more times is not particularly limited, but preferred examples thereof include a method of circulating the composition in a device including the filters, a method of passing through a plurality of filters connected in series one or more times each, a method of re-filtering with the same or a different filter after filtration with a certain filter, and a method of combining these methods.

[Speed of Passing Through Filter]

A speed at which the precursor composition 2 passes through the filter in the second filtering step is not particularly limited, but is preferably 1.0 to 100.0 cm/min and more preferably 5.0 to 50.0 cm/min.

[Effective Filtration Area]

An effective filtration area of the filter in the second filtering step is preferably 300 cm² or greater, more preferably 500 cm² or greater, and still more preferably 1,000 cm² or greater. The upper limit thereof is not particularly limited, and for example, may be 50,000 cm² or lower.

A filtration pressure (applied pressure) in the second filtering step may vary depending on the material of the filter and the filtration device, the chemical structure of components included in the precursor composition 2, and the like, but it is preferably 0.5 MPa or lower, more preferably 0.3 MPa or lower, still more preferably 0.2 MPa or lower, and particularly preferably 0.1 MPa or lower. By setting such a range, it is possible to more effectively suppress particles of impurities from passing through the filter due to the impurities.

The lower limit of the above-described filtration pressure is not particularly limited, but is preferably 0.05 MPa or greater.

In the present invention, an average flow rate of the precursor composition 2 is preferably 20 cm³ or greater per minute, and more preferably 100 cm³ to 3000 cm³ per minute.

Among the filters used in the second filtering step, it is preferable that a pore diameter of at least one of the filters is 500 nm or lower, and it is more preferable that the pore diameters of all filters are 300 nm or lower.

The pore diameter is more preferably 200 nm or lower, and still more preferably 1 nm to 100 nm. By passing the precursor composition 2 through the filter having the above-described pore diameter, the foreign substance can be efficiently removed.

Moreover, it is preferable that the pore diameter of the filter used in the second filtering step is smaller than the pore diameter of the filter used in the first filtering step.

A material of the filter used in the second filtering step is not particularly specified, but a cellulose-based resin, a polypropylene-based resin, a fluorine-based resin, a polyethylene-based resin, a nylon-based resin, or the like can be preferably used.

In particular, it is preferable that at least one filter used in the second filtering step is polyethylene, polypropylene, nylon, or polytetrafluoroethylene.

Examples of the filter used in the second filtering step include a membrane filter and a depth filter, and a known filter can be used without particular limitation, but a membrane filter is preferable.

By using the membrane filter, it is possible to prevent gel-like impurities and the like from passing through the filter while being deformed in the filter.

Moreover, it is preferable that at least one type of the filter used in the second filtering step is a filter cartridge obtained by processing the membrane filter into a pleated shape. The filter cartridge processed into a pleated shape has an advantage in that the effective filtration area can be produced.

A temperature of the precursor composition 2 in the second filtering step may or may not be adjusted.

For example, the temperature of the precursor composition 2 may be set in a range of 10° C. to 40° C. for the filtration, and the temperature thereof is also preferably set to 15° C. to 30° C.

<Other Steps>

The method for producing a composition for forming an interlayer for nanoimprint according to the embodiment of the present invention may further include a step other than the first filtering step, the preparing step, and the second filtering step.

As other steps, a step of removing a salt component or the like from the precursor composition 1 or the precursor composition 2 using an ion exchange resin may be included.

Hereinafter, each component included in the composition for forming an interlayer for nanoimprint will be described.

Details of each component included in the composition for forming an interlayer for nanoimprint and details of each component included in the precursor composition 1 or the precursor composition 2 are the same, except that the concentration of solid contents in the precursor composition 1 is within the above-described range.

That is, it is preferable that a component preferably included in the composition for forming an interlayer for nanoimprint is also included in the precursor composition 1 or the precursor composition 2, except that the concentration of solid contents in the precursor composition 1 is within the above-described range, and a content thereof is also the same in the composition for forming an interlayer for nanoimprint, the precursor composition 1, or the precursor composition 2.

<Composition for Forming Interlayer for Nanoimprint>

[Resin Having Polymerizable Group]

The composition for forming an interlayer includes a resin having a polymerizable group.

A content of the resin having a polymerizable group in the composition for forming an interlayer is not particularly limited, but is preferably 50% by mass or greater in the total solid content, more preferably 70% by mass or greater in the total solid content, and still more preferably 80% by mass or greater in the total solid content. The upper limit thereof is not particularly limited, but is preferably 99.9% by mass or lower.

A concentration of the resin having a polymerizable group in the composition for forming an interlayer (including a solvent) is not particularly limited, but is preferably 0.01% by mass or greater, more preferably 0.05% by mass or greater, and still more preferably 0.1% by mass or greater. The upper limit thereof is preferably 10% by mass or lower, more preferably 5% by mass or lower, still more preferably 1% by mass or lower, and even more preferably lower than 1% by mass.

As the resin having a polymerizable group, a well-known resin can be widely used.

The polymerizable group is not particularly limited, and preferred examples thereof include a radically polymerizable group.

Moreover, it is preferable that the resin having a polymerizable group further has a polar group.

By having the radically polymerizable group, an interlayer having excellent hardness can be obtained. Moreover, by having the polar group, adhesiveness to the base material is improved. Furthermore, in a case where a crosslinking agent is formulated, a crosslinking structure formed after curing is further firmed, and thus hardness of the obtained interlayer can be improved.

The radically polymerizable group preferably includes an ethylenically unsaturated bond-containing group. Examples of the ethylenically unsaturated bond-containing group include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group, and a (meth)acryloyl group or a vinyl group is preferable, a (meth)acryloyl group is more preferable, and a (meth)acryloyloxy group is still more preferable. The ethylenically unsaturated bond-containing group defined here is referred to as Et.

Furthermore, the polar group is preferably at least one kind of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphoric acid group, a carboxy group, or a hydroxy group, more preferably at least one kind of an alcoholic hydroxy group, a phenolic hydroxy group, or a carboxy group, and still more preferably an alcoholic hydroxy group or a carboxy group. The polar group defined here is referred to as a polar group Po. The polar group is preferably a nonionic group.

The resin having a polymerizable group may further include a cyclic ether group. Examples of the cyclic ether group include an epoxy group and an oxetanyl group, and an epoxy group is preferable. The cyclic ether group defined here is referred to as a cyclic ether group Cyt.

Examples of the resin include a (meth)acrylic resin, a vinyl resin, a novolac resin, a phenol resin, a melamine resin, a urea resin, an epoxy resin, and a polyimide resin, and at least one kind of a (meth)acrylic resin, a vinyl resin, or a novolac resin is preferable.

A weight-average molecular weight of the resin is preferably 4,000 or more, more preferably 6,000 or more, and still more preferably 8,000 or more. The upper limit thereof is preferably 1,000,000 or less and may be 500,000 or less.

The resin preferably has at least one of constitutional units represented by Formulae (1) to (3).

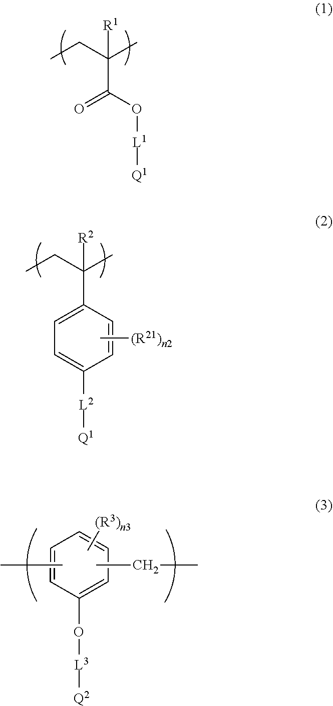

In the formulae, R¹ and R² are each independently a hydrogen atom or a methyl group. R²¹ and R³ are each independently a substituent. L¹, L², and L³ are each independently a single bond or a linking group. n2 is an integer of 0 to 4. n3 is an integer of 0 to 3. Q¹ is an ethylenically unsaturated bond-containing group or a cyclic ether group. Q² is an ethylenically unsaturated bond-containing group, a cyclic ether group, or a polar group.

R¹ and R² are each preferably a methyl group.

R²¹ and R³ are each independently preferably the substituent T.

In a case where there is a plurality of R²¹'s, R²¹'s may be linked to each other to form a cyclic structure. In the present specification, the linking is meant to include not only an aspect in which groups are continued by bonding but also an aspect in which groups lose some atoms and are fused (condensed). Moreover, unless otherwise specified, an oxygen atom, a sulfur atom, and a nitrogen atom (amino group) may be included in the linking cyclic structure. Examples of the formed cyclic structure include an aliphatic hydrocarbon ring (groups exemplified below are referred to as a ring Cf) (for example, a cyclopropyl group, a cyclobutyl group, a cyclopentyl group, a cyclohexyl group, a cyclopropenyl group, a cyclobutenyl group, a cyclopentenyl group, a cyclohexenyl group, and the like), an aromatic hydrocarbon ring (rings exemplified below are referred to as a ring Cr) (a benzene ring, a naphthalene ring, an anthracene ring, a phenanthrene ring, and the like), a nitrogen-containing heterocycle (rings exemplified below are referred to as a ring Cn) (for example, a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, a morpholine ring, and the like), an oxygen-containing heterocycle (rings exemplified below are referred to as a ring Co) (a furan ring, a pyran ring, an oxirane ring, an oxetane ring, a tetrahydrofuran ring, a tetrahydropyran ring, a dioxane ring, and the like), and a sulfur-containing heterocycle (rings exemplified below are referred to as a ring Cs) (a thiophene ring, a thiirane ring, a thietane ring, a tetrahydrothiophene ring, a tetrahydrothiopyran ring, and the like).

In a case where there is a plurality of R³'s, R³'s may be linked to each other to form a cyclic structure. Examples of the formed cyclic structure include ring Cf, the ring Cr, the ring Cn, the ring Co, and the ring Cs.

It is preferable that L¹, L², and L³ are each independently a single bond or a linking group L which will be described later. Among them, a single bond, or an alkylene group or an (oligo)alkyleneoxy group, which is defined as the linking group L, is preferable, and an alkylene group is more preferable. The linking group L preferably has the polar group Po as a substituent. Moreover, an aspect in which the alkylene group has a hydroxy group as a substituent is also preferable. In the present specification, the “(oligo)alkyleneoxy group” means a divalent linking group having one or more “alkyleneoxy” constitutional units. The number of carbon atoms in an alkylene chain in the constitutional unit may be the same or different for every constitutional unit.

n2 is preferably 0 or 1 and more preferably 0. n3 is preferably 0 or 1 and more preferably 0.

Q¹ is preferably the ethylenically unsaturated bond-containing group Et.

Q² is preferably a polar group, and preferably an alkyl group having an alcoholic hydroxy group.

The above-described resin may further include at least one of a constitutional unit (11), a constitutional unit (21), or a constitutional unit (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

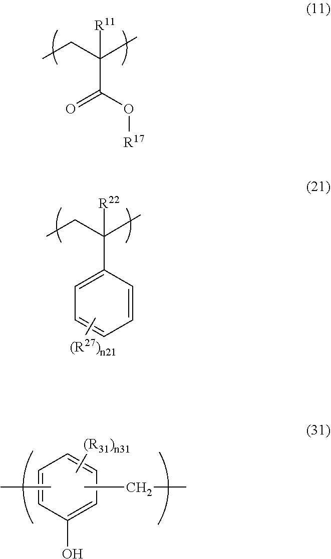

In the formulae, R¹¹ and R²² are each independently a hydrogen atom or a methyl group. R¹⁷ is a substituent. R²⁷ is a substituent. n21 is an integer of 0 to 5. R³¹ is a substituent, and n31 is an integer of 0 to 3.

R¹¹ and R²² are each preferably a methyl group.

R¹⁷ is preferably a group containing a polar group or a group containing a cyclic ether group. In a case where R¹⁷ is a group containing a polar group, R¹⁷ is preferably a group containing the polar group Po, and more preferably the polar group Po or the substituent T substituted with the polar group Po. In a case where R¹⁷ is a group containing a cyclic ether group, R¹⁷ is preferably a group containing the cyclic ether group Cyt, and more preferably the substituent T substituted with the cyclic ether group Cyt.

R²⁷ is a substituent, and at least one of R²⁷'s is preferably a polar group. The substituent is preferably the substituent T. n21 is preferably 0 or 1 and more preferably 0. In a case where there is a plurality of R′'s, R′'s may be linked to each other to form a cyclic structure. Examples of the formed cyclic structure include examples of the ring Cf, the ring Cr, the ring Cn, the ring Co, and the ring Cs.

R³¹ is preferably the substituent T. n31 is an integer of 0 to 3, preferably 0 or 1, and more preferably 0. In a case where there is a plurality of R³¹'s, R³¹'s may be linked to each other to form a cyclic structure. Examples of the formed cyclic structure include examples of the ring Cf, the ring Cr, the ring Cn, the ring Co, and the ring Cs.

Examples of the linking group L include an alkylene group (the number of carbon atoms is preferably 1 to 24, more preferably 1 to 12, and still more preferably 1 to 6), an alkenylene group (the number of carbon atoms is preferably 2 to 12, more preferably 2 to 6, and still more preferably 2 or 3), an (oligo)alkyleneoxy group (the number of carbon atoms in an alkylene group in one constitutional unit is preferably 1 to 12, more preferably 1 to 6, and still more preferably 1 to 3; and the repetition number is preferably 1 to 50, more preferably 1 to 40, and still more preferably 1 to 30), an arylene group (the number of carbon atoms is preferably 6 to 22, more preferably 6 to 18, and still more preferably 6 to 10), an oxygen atom, a sulfur atom, a sulfonyl group, a carbonyl group, a thiocarbonyl group, —NR^{N}—, and a linking group related to a combination thereof. The alkylene group, alkenylene group, and alkyleneoxy group may have the substituent T. For example, the alkylene group may have a hydroxy group.

A linking chain length of the linking group L is preferably 1 to 24, more preferably 1 to 12, and still more preferably 1 to 6. The linking chain length means the number of atoms positioned on the shortest path among the atomic groups involved in the linkage. For example, in a case of —CH₂—(C═O)—O—, the linking chain length is 3.

Furthermore, the alkylene group, alkenylene group, and (oligo)alkyleneoxy group, which are defined as the linking group L, may be chain-like or cyclic, or may be linear or branched.

It is preferable that as an atom constituting the linking group L, a carbon atom, a hydrogen atom, and as necessary, a heteroatom (at least one kind selected from an oxygen atom, a nitrogen atom, or a sulfur atom, and the like) are included. The number of carbon atoms in the linking group is preferably 1 to 24, more preferably 1 to 12, and still more preferably 1 to 6. The number of hydrogen atom may be determined according to the number of carbon atoms and the like. In a case of the number of heteroatoms, the numbers of the oxygen atoms, the nitrogen atoms, and the sulfur atoms are each independently preferably 0 to 12, more preferably 0 to 6, and still more preferably 0 to 3.

The resin may be synthesized by a conventional method. For example, a resin having the constitutional unit represented by Formula (1) can be appropriately synthesized by a well-known method for addition polymerization of olefin. A resin having the constitutional unit represented by Formula (2) can be appropriately synthesized by a well-known method for addition polymerization of styrene. A resin having the constitutional unit represented by Formula (3) can be appropriately synthesized by a well-known method for synthesis of a phenol resin.

The resin may be used alone or in combination of a plurality thereof.

As the resin as the curable component, in addition to the above-described resins, the resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used, the contents of which are incorporated in the present specification.

[Solvent]

In the present invention, the composition for forming an interlayer particularly preferably contains a solvent (hereinafter, also referred to as a “solvent for an interlayer”). The solvent is, for example, preferably a compound which is liquid at 23° C. and has a boiling point of 250° C. or lower. The composition for forming an interlayer contains the solvent for an interlayer in an amount of 99.0% by mass or greater, preferably 99.2% by mass or greater, and may contain the solvent for an interlayer in an amount of 99.4% by mass or greater.

That is, a proportion of the total solid content of the composition for forming an interlayer to the total mass of the composition for forming an interlayer is 0.1% to 1.0% by mass.

The above-described proportion of the total solid content is preferably 0.8% by mass or lower, and more preferably 0.6% by mass or lower. In addition, the lower limit value thereof is preferably greater than 0.1% by mass, and more preferably 0.2% by mass or greater.

By setting the proportion of the solvent within the above-described range, a film thickness during film formation is kept thin, and thus pattern formability during etching processing tends to be improved.

Only one kind or two or more kinds of the solvents may be contained in the composition for forming an interlayer. In a case where two or more kinds thereof are contained, the total amount thereof is preferably within the above-described range.

A boiling point of the solvent for an interlayer is preferably 230° C. or lower, more preferably 200° C. or lower, still more preferably 180° C. or lower, even more preferably 160° C. or lower, and further still more preferably 130° C. or lower. The lower limit value thereof is preferably 23° C. and more preferably 60° C. or higher. By setting the boiling point within the above-described range, the solvent can be easily removed from the interlayer, which is preferable.

The solvent for an interlayer is preferably an organic solvent. The solvent is preferably a solvent having any one or more of an ester group, a carbonyl group, a hydroxy group, or an ether group. Among them, it is preferable to use an aprotic polar solvent.

Examples of a preferred solvent among the solvents for an interlayer include alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate, and propylene glycol monoalkyl ether and lactone are particularly preferable.

[Crosslinking Agent]

The crosslinking agent in the composition for forming an interlayer is not particularly limited as long as the crosslinking agent advances curing by a crosslinking reaction. In the present invention, the crosslinking agent is preferably reacted with a polar group of a resin to form a crosslinking structure. By using such a crosslinking agent, the resin is more firmly bonded, and thus a firmer film can be obtained.

Examples of the crosslinking agent include an epoxy compound (compound having an epoxy group), an oxetanyl compound (compound having an oxetanyl group), an alkoxymethyl compound (compound having an alkoxymethyl group), a methylol compound (compound having a methylol group), and a blocked isocyanate compound (compound having a blocked isocyanate group), and an alkoxymethyl compound (compound having an alkoxymethyl group) can form a firm bond at a low temperature and thus is preferable.

[Other Components]

The composition for forming an interlayer may include other components in addition to the above-described components.

Specifically, one kind or two or more kinds of a thermal acid generator, an alkylene glycol compound, a polymerization initiator, a polymerization inhibitor, an antioxidant, a leveling agent, a thickener, a surfactant, or the like may be included. Regarding the above-described components, the respective components described in JP2013-036027A, JP2014-090133A, and JP2013-189537A can be used. Also regarding the content or the like, reference can be made to the description in the above-described publications.

—Thermal acid generator—

The thermal acid generator is a compound which generates an acid by heating and advances crosslinking by the action of the acid. In a case of being used in combination with the crosslinking agent, an interlayer having higher hardness can be obtained.

As the thermal acid generator, an organic onium salt compound in which a cationic component and an anionic component are paired is usually used. As the cationic component, for example, organic sulfonium, organic oxonium, organic ammonium, organic phosphonium, and organic iodonium can be mentioned. Moreover, as the above-described anionic component, for example, BF⁴⁻, B(C₆F₅)⁴⁻, SbF⁶⁻, AsF⁶⁻, PF⁶⁻, CF₃SO₃⁻, C₄F₉SO₃⁻, and (CF₃SO₂)₃C⁻ can be mentioned.

Specifically, reference can be made to the description in paragraphs 0243 to 0256 of JP2017-224660A and paragraph 0016 of JP2017-155091A, the contents of which are incorporated in the present specification.

A content of the thermal acid generator is preferably 0.01 to 10 parts by mass and more preferably 0.1 to 5 parts by mass, with respect to 100 parts by mass of the crosslinking agent. The thermal acid generator may be used alone or in combination of two or more kinds thereof. In a case where two or more kinds thereof are used, the total amount thereof is preferably within the above-described range.

—Alkylene Glycol Compound—

The composition for forming an interlayer may include an alkylene glycol compound. In the alkylene glycol compound, the number of alkylene glycol constitutional units is preferably 3 to 1,000, more preferably 4 to 500, still more preferably 5 to 100, and even more preferably 5 to 50. A weight-average molecular weight (Mw) of the alkylene glycol compound is preferably 150 to 10,000, more preferably 200 to 5,000, still more preferably 300 to 3,000, and even more preferably 300 to 1,000.

Examples of the alkylene glycol compound include polyethylene glycol, polypropylene glycol, mono- or dimethyl ether thereof, mono- or dioctyl ether, mono- or dinonyl ether, mono- or didecyl ether, monostearic acid ester, monooleic acid ester, monoadipic acid ester, and monosuccinic acid ester, and polyethylene glycol or polypropylene glycol is preferable.

A surface tension of the alkylene glycol compound at 23° C. is preferably 38.0 mN/m or greater and more preferably 40.0 mN/m or greater. The upper limit of the surface tension is not particularly specified, but is, for example, 48.0 mN/m or lower. By formulating such a compound, wettability of the composition for forming a pattern applied immediately above the interlayer can be further improved.

The surface tension is measured at 23° C. using a surface tensiometer SURFACE TENS-IOMETER CBVP-A3 manufactured by Kyowa Interface Science Co., LTD. and a glass plate. The unit is mN/m. Two samples are produced for one level and are respectively measured three times. An arithmetic mean value of a total of six times is adopted as an evaluation value.

In a case where the composition for forming an interlayer contains an alkylene glycol compound, a content thereof is preferably 40% by mass or lower of the solid content of the composition for forming an interlayer, more preferably 30% by mass or lower, still more preferably 20% by mass or lower, and particularly preferably 1% to 15% by mass. The alkylene glycol compound may be used alone or in combination of two or more kinds thereof. In a case where two or more kinds thereof are used, the total amount thereof is preferably within the above-described range.

—Polymerization Initiator—

The composition for forming an interlayer may contain a polymerization initiator and preferably contains at least one kind of a thermal polymerization initiator or a photopolymerization initiator. Moreover, it is not necessary that the composition for forming an interlayer contain the polymerization initiator. By containing the polymerization initiator, a reaction of a polymerizable group contained in the composition for forming an interlayer is promoted, and thus the adhesiveness tends to be improved. From the viewpoint that crosslinking reactivity with the composition for forming a pattern is improved, a photopolymerization initiator is preferable. As the photopolymerization initiator, a radical polymerization initiator or a cationic polymerization initiator is preferable, and a radical polymerization initiator is more preferable. Moreover, in the present invention, a plurality of kinds of photopolymerization initiators may be used in combination.

As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an aminoacetophenone compound, hydroxyacetophenone, an azo-based compound, an azide compound, a metallocene compound, an organic boron compound, and an iron arene complex. For the details thereof, reference can be made to the description in paragraphs 0165 to 0182 of JP2016-027357A, the contents of which are incorporated in the present specification.

Examples of the acylphosphine compound include 2,4,6-trimethylbenzoyl-diphenyl-phosphine oxide. Moreover, IRGACURE 819, IRGACURE 1173, and IRGACURE TPO (trade names; all are manufactured by BASF SE), which are commercially available products, can be used.

In a case where the photopolymerization initiator used in the composition for forming an interlayer is formulated, a content thereof in the total solid content is, for example, 0.0001% to 5% by mass, preferably 0.0005% to 3% by mass, and more preferably 0.01% to 1% by mass. In a case where two or more kinds of photopolymerization initiators are used, the total amount thereof is within the above-described range.

<Curable Layer and Composition for Forming Pattern>

A composition for forming an interlayer obtained by the method for producing a composition for forming an interlayer for nanoimprint according to the embodiment of the present invention is used for forming an interlayer existing between the base material and the curable layer.

The curable layer is not particularly limited, but is preferably a curable layer formed from a composition for forming a pattern.

Moreover, the curable layer is preferably a photocurable layer.

Composition of the composition for forming a pattern is not particularly specified, but it is preferable to contain a polymerizable compound, more preferable to contain a polymerization initiator and a polymerizable compound, still more preferable to contain a radical polymerization initiator and a radically polymerizable compound, and particularly preferable to contain a photoradical polymerization initiator and a radically polymerizable compound.

[Polymerizable Compound]

The composition for forming a pattern preferably contains a polymerizable compound, and it is preferable that a component having the highest content of components contained in the composition for forming a pattern, other than a solvent, is the polymerizable compound. The polymerizable compound may have one polymerizable group or two or more polymerizable groups in one molecule. At least one kind of polymerizable compounds included in the composition for forming a pattern preferably has two to five polymerizable groups, more preferably has two to four polymerizable groups, still more preferably has two or three polymerizable groups, and even more preferably has three polymerizable groups, in one molecule.

The type of the polymerizable group included in the polymerizable compound is not particularly specified, and examples thereof include a group having an ethylenically unsaturated group and a cyclic ether group (an epoxy group, a glycidyl group, and an oxetanyl group). Among them, a group having an ethylenically unsaturated group is preferable. Examples of the group having an ethylenically unsaturated group include a (meth)acryloyl group, a (meth)acryloyloxy group, a (meth)acryloylamino group, a vinyl group, a vinyloxy group, an allyl group, and a vinylphenyl group. Among them, a (meth)acryloyl group or a (meth)acryloyloxy group is more preferable, and an acryloyl group or an acryloyloxy group is still more preferable.

In addition, the polymerizable group included in the polymerizable compound is preferably a group which can react with the polymerizable group in the above-described resin having a polymerizable group of the composition for forming an interlayer.

At least one kind of polymerizable compounds included in the composition for forming a pattern preferably has a cyclic structure. Examples of this cyclic structure include an aliphatic hydrocarbon ring Cf and an aromatic hydrocarbon ring Cr. Among these, the polymerizable compound preferably has the aromatic hydrocarbon ring Cr and more preferably has a benzene ring.

A molecular weight of the polymerizable compound is preferably 100 to 900.

The at least one kind of the above-described polymerizable compounds is preferably represented by Formula (I-1).

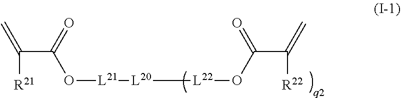

L²⁰ is a (1+q2)-valent linking group, and examples thereof include a linking group having a cyclic structure. Examples of the cyclic structure include examples of the ring Cf, the ring Cr, the ring Cn, the ring Co, and the ring Cs.

R²¹ and R²² each independently represent a hydrogen atom or a methyl group.

L²¹ and L²² each independently represent a single bond or the linking group L. L²⁰ and L²¹ or L²² may be bonded to each other via or without via the linking group L to form a ring. L²⁰, L²¹, and L²² may have the substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, and still more preferably 0 or 1.

—High-Molecular-Weight Polymerizable Compound—

Moreover, the composition for forming a pattern may contain, as the polymerizable compound, a polymerizable compound having a weight-average molecular weight of 800 or more (hereinafter, also referred to as a “high-molecular-weight polymerizable compound”).

By using the high-molecular-weight polymerizable compound, a transfer of the polymerization inhibitor from the interlayer to the curable layer is easily suppressed, and it is presumed that the pattern defects are easily suppressed.

Examples of the high-molecular-weight polymerizable compound include a compound (silicon-containing compound) containing a silicon atom (Si), a compound (ring-containing compound) containing a cyclic structure, and a dendrimer-type compound, and a silicon-containing compound or a ring-containing compound is preferable and a silicon-containing compound is more preferable.

A weight-average molecular weight of the high-molecular-weight polymerizable compound is 800 or more, preferably 1,000 or more, more preferably 1,500 or more, and still more preferably more than 2,000. The upper limit of the weight-average molecular weight is not particularly specified, but for example, 100,000 or less is preferable, 50,000 or less is more preferable, 10,000 or less is still more preferable, 8,000 or less is even more preferable, 5,000 or less is even still more preferable, 3,500 or less is particularly preferable, and 3,000 or less is more particularly preferable. By setting the molecular weight to the above-described lower limit value or more, a volatility of the compound is suppressed, and characteristics of the composition or a coating film are stabilized. Moreover, good viscosity for maintaining a morphology of the coating film can be ensured. Further, it is possible to realize good releasability of the film by complementing the effect of suppressing a mold release agent to a small amount. By setting the molecular weight to the above-described upper limit value or less, it is easy to secure a low viscosity (fluidity) required for pattern filling, which is preferable.

<<Silicon-Containing Compound >>

Examples of the silicon-containing compound include a compound having a silicone skeleton. Specific examples thereof include a compound having at least one of a D-unit siloxane structure represented by Formula (S1) or a T-unit siloxane structure represented by Formula (S2).

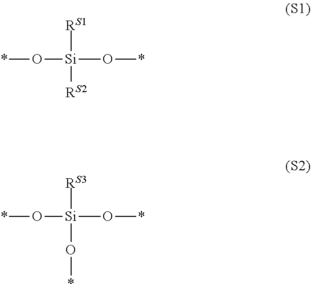

In Formula (S1) or Formula (S2), R^{S1} to R^{S3} each independently represent a hydrogen atom or a monovalent substituent, and *'s each independently represent a bonding site with other structures.

R^{S1} to R^{S3} are each independently preferably a monovalent substituent.

As the above-described monovalent substituent, an aromatic hydrocarbon group (preferably having 6 to 22 carbon atoms, more preferably having 6 to 18 carbon atoms, and still more preferably having 6 to 10 carbon atoms) or an aliphatic hydrocarbon group (preferably having 1 to 24 carbon atoms, more preferably having 1 to 12 carbon atoms, and still more preferably having 1 to 6 carbon atoms) is preferable, and among them, a cyclic or chain (linear or branched) alkyl group (preferably having 1 to 12 carbon atoms, more preferably having 1 to 6 carbon atoms, and still more preferably having 1 to 3 carbon atoms) or a group including a polymerizable group is preferable.

Specific examples of a structure of the silicon-containing compound include the following examples of Formulae (s-1) to (s-9) in terms of partial structure. Q in the formulae is a group including the above-described polymerizable group. A plurality of these structures may be present in the compound, or may be present in combination.

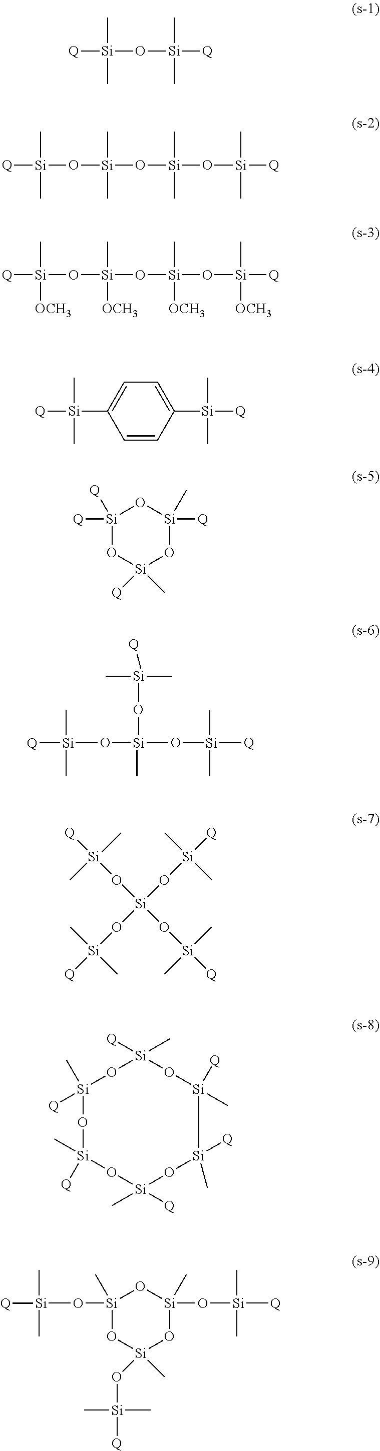

The silicon-containing compound is preferably a reactant of a silicone resin and a compound having a polymerizable group.

As the above-described silicone resin, a reactive silicone resin is preferable.

Examples of the reactive silicone resin include a modified silicone resin having the above-described silicone skeleton, and for example, a monoamine-modified silicone resin, a diamine-modified silicone resin, a special amino-modified silicone resin, an epoxy-modified silicone resin, an alicyclic epoxy-modified silicone resin, a carbinol-modified silicone resin, a mercapto-modified silicone resin, a carboxy-modified silicone resin, a hydrogen-modified silicone resin, an amino-polyether-modified silicone resin, an epoxy-polyether-modified silicone resin, an epoxy-aralkyl-modified silicone resin, and the like can be mentioned.

As the above-described compound having a polymerizable group, a compound having a polymerizable group and a group capable of reacting with an alkoxysilyl group or a silanol group is preferable, and a compound having a polymerizable group and a hydroxy group is more preferable.

Moreover, in a case where the above-described modified silicone resin is used as the silicone resin, as the above-described compound having a polymerizable group, a compound having a polymerizable group and a group which reacts with an amino group, an epoxy group, a mercapto group, a carboxy group, and the like, which are included in the above-described modified silicone resin, may be used.

A preferred aspect of the polymerizable group in the above-described compound having a polymerizable group is the same as the preferred aspect of the polymerizable group in the above-described polymerizable compound.

As the above-described compound having a polymerizable group, among them, hydroxyalkyl (meth)acrylate is preferable, and 2-hydroxyethyl (meth)acrylate is more preferable.

More specifically, a reactant of a compound having a polymerizable group and a group (for example, a hydroxy group) capable of reacting with an alkoxysilyl group or a silanol group and a silicone resin having an alkoxysilyl group or a silanol group is preferable.

<<Ring-Containing Compound>>

Examples of a cyclic structure of the compound (ring-containing compound) containing a ring include an aromatic ring and an alicyclic ring. Examples of the aromatic ring include an aromatic hydrocarbon ring and an aromatic heterocyclic ring.

The aromatic hydrocarbon ring preferably has 6 to 22 carbon atoms, more preferably has 6 to 18 carbon atoms, and still more preferably has 6 to 10 carbon atoms. Specific examples of the aromatic hydrocarbon ring include a benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring. Among them, a benzene ring or a naphthalene ring is preferable, and a benzene ring is more preferable. The aromatic ring may have a structure in which a plurality of rings is linked to each other, and examples thereof include a biphenyl structure and a diphenylalkane structure (for example, 2,2-diphenylpropane) (the aromatic hydrocarbon ring specified here is referred to as aCy).

The aromatic heterocyclic ring preferably has 1 to 12 carbon atoms, more preferably has 1 to 6 carbon atoms, and still more preferably has 1 to 5 carbon atoms. Specific examples thereof include a thiophene ring, a furan ring, a dibenzofuran ring, a pyrrole ring, an imidazole ring, a benzimidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, a pyridazine ring, an isoindole ring, an indole ring, an indazole ring, a purine ring, a quinolidine ring, an isoquinoline ring, a quinoline ring, a phthalazine ring, a naphthylidine ring, a quinoxaline ring, a quinazoline ring, a cinnoline ring, a carbazole ring, an acridine ring, a phenazine ring, a phenothiazine ring, a phenoxathiin ring, and a phenoxazine ring (the aromatic heterocyclic ring specified here is referred to as hCy).

The alicyclic ring preferably has 3 to 22 carbon atoms, more preferably has 4 to 18 carbon atoms, and still more preferably has 6 to 10 carbon atoms. Specific examples of the aliphatic hydrocarbon ring include a cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydrodicyclopentadiene ring, an octahydronaphthalene ring, a decahydronaphthalene ring, a hexahydroindane ring, a bornane ring, a norbornane ring, a norbornene ring, a isobornane ring, a tricyclodecane ring, a tetracyclododecane ring, and an adamantane ring. Examples of the aliphatic hetero ring include a pyrrolidine ring, an imidazolidine ring, a piperidine ring, a piperazine ring, a morpholine ring, an oxirane ring, an oxetane ring, an oxolane ring, an oxane ring, and a dioxane ring (the alicyclic ring specified here is referred to as fCy).

In the present invention, in a case where the high-molecular-weight polymerizable compound is a ring-containing compound, a compound containing an aromatic hydrocarbon ring is preferable, and a compound having a benzene ring is more preferable. Examples thereof include a compound having a structure represented by Formula (C-1).

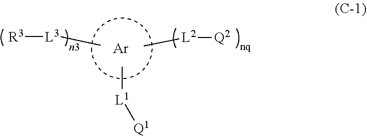

In the formula, Ar represents the above-described aromatic hydrocarbon ring or aromatic heterocyclic ring.

L¹ and L² are each independently a single bond or a linking group. Examples of the linking group include an oxygen atom (oxy group), a carbonyl group, an amino group, an alkylene group (preferably having 1 to 12 carbon atoms, more preferably having 1 to 6 carbon atoms, and still more preferably 1 to 3 carbon atoms), and a group of a combination of these groups. Among them, a (poly)alkyleneoxy group is preferable. The (poly)alkyleneoxy group may be a group having one alkyleneoxy group or a group in which a plurality of alkyleneoxy groups is repeatedly linked. Moreover, an order of the alkylene group and the oxy group is not limited. The repetition number of the alkyleneoxy group is preferably 1 to 24, more preferably 1 to 12, and still more preferably 1 to 6. Moreover, the (poly)alkyleneoxy group may be intervened with an alkylene group (preferably having 1 to 24 carbon atoms, more preferably having 1 to 12 carbon atoms, and still more preferably having 1 to 6 carbon atoms) in relation to linking with the ring Ar which is a mother nucleus or with the polymerizable group Q. Therefore, (poly)alkyleneoxy=alkylene group may be used.

R³ is an optional substituent, and examples thereof include an alkyl group (preferably having 1 to 12 carbon atoms, more preferably having 1 to 6 carbon atoms, and still more preferably having 1 to 3 carbon atoms), an alkenyl group (preferably having 2 to 12 carbon atoms, more preferably having 2 to 6 carbon atoms, and still more preferably having 2 or 3 carbon atoms), an aryl group (preferably having 6 to 22 carbon atoms, more preferably having 6 to 18 carbon atoms, and still more preferably having 6 to 10 carbon atoms), an arylalkyl group (preferably having 7 to 23 carbon atoms, more preferably having 7 to 19 carbon atoms, and still more preferably having 7 to 11 carbon atoms), a hydroxy group, a carboxy group, an alkoxy group (preferably having 1 to 24 carbon atoms, more preferably having 1 to 12 carbon atoms, and still more preferably having 1 to 6 carbon atoms), an acyl group (preferably having 2 to 12 carbon atoms, more preferably having 2 to 6 carbon atoms, and still more preferably having 2 or 3 carbon atoms; also preferably an alkylcarbonyl group), and an aryloyl group (preferably having 7 to 23 carbon atoms, more preferably having 7 to 19 carbon atoms, and still more preferably having 7 to 11 carbon atoms).

L³ is a single bond or a linking group. Examples of the linking group include the examples of L¹ and L² described above.

n3 is preferably 3 or less, more preferably 2 or less, still more preferably 1 or less, and particularly preferably 0.

Q¹ and Q² are each independently a polymerizable group, and the example of the above-described polymerizable group is preferable.

In the ring-containing compound, in a case where the number of side chains having a polymerizable group is increased, it is possible to form a strong crosslinking structure during curing, and the resolution tends to be improved. From this viewpoint, nq is 1 or more, preferably 2 or more. The upper limit thereof is preferably 6 or less, more preferably 4 or less, and still more preferably 3 or less.

Similarly, from the viewpoint of easily forming a uniform crosslinking structure, in a case where a group including a polymerizable group or a substituent is introduced into the cyclic structure, it is preferable that the substituents are arranged in series.

<<Dendrimer-Type Compound>>

The high-molecular-weight polymerizable compound may be a dendrimer-type compound. The dendrimer means a dendritic polymer having a structure which branches regularly from a center. The dendrimer is composed of a central molecule (stem) called as a core and a side chain portion (branch) called as a dendron. As a whole, a fan-shaped compound is common, but a dendrimer in which dendrons are spread in a semicircular or circular shape may be used. A group having a polymerizable group can be introduced into a dendron portion (for example, a terminal portion away from the core) of the dendrimer to obtain the polymerizable compound. In a case where a (meth)acryloyl group is used as the polymerizable group to be introduced, a dendrimer-type polyfunctional (meth)acrylate can be obtained.

For the dendrimer-type compound, for example, matters described in JP5512970B can be referred to, the description of which is incorporated in the present specification.

<<Polymerizable Group Equivalent>>

A polymerizable group equivalent of the high-molecular-weight polymerizable compound is preferably 130 or more, more preferably 150 or more, still more preferably 160 or more, even more preferably 190 or more, and even still more preferably 240 or more. The upper limit value of the polymerizable group equivalent is preferably 2,500 or less, more preferably 1,800 or less, still more preferably 1,000 or less, even more preferably 500 or less, and even still more preferably 350 or less, and may be 300 or less.

The polymerizable group equivalent is calculated by the following expression.

(Polymerizable group equivalent)=(Number-average molecular weight of polymerizable compound)/(Number of polymerizable groups in polymerizable compound)

In a case where the polymerizable group equivalent of the high-molecular-weight polymerizable compound is the above-described lower limit value or more, it is considered that the elastic modulus during curing is in an appropriate range and the releasability is excellent. On the other hand, in a case where the polymerizable group equivalent is the above-described upper limit value or less, it is considered that a crosslinking density of the cured substance pattern is in an appropriate range and the resolution of the transfer pattern is excellent.

In a case of the silicon-containing compound, the number of polymerizable groups in the high-molecular-weight polymerizable compound is preferably 2 or more, more preferably 3 or more, and still more preferably 4 or more in one molecule. The upper limit thereof is preferably 50 or less, more preferably 40 or less, still more preferably 30 or less, and even more preferably 20 or less.

In a case of the ring-containing compound, it is preferable to be 2 or more in one molecule. The upper limit thereof is preferably 4 or less and more preferably 3 or less.

Alternatively, in a case of the dendrimer-type compound, it is preferable to be 5 or more, more preferably 10 or more, and still more preferably 20 or more in one molecule. The upper limit thereof is preferably 1,000 or less, more preferably 500 or less, and still more preferably 200 or less.

<<Viscosity>>

A viscosity of the high-molecular-weight polymerizable compound at 23° C. is preferably 100 mPa·s or greater, more preferably 120 mPa·s or greater, and still more preferably 150 mPa·s or greater. The upper limit value of the above-described viscosity is preferably 2,000 mPa·s or lower, more preferably 1,500 mPa·s or lower, and still more preferably 1,200 mPa·s or lower.

Unless otherwise specified, the viscosity in the present specification is a value measured with an E-type rotational viscometer RE85L manufactured by TOKI SANGYO CO., LTD. and a standard cone rotor (1° 34′×R²⁴) in a state where a temperature of a sample cup is adjusted to 23° C. Other details regarding the measurement are in accordance with JIS Z 8803:2011. Two samples are produced for one level and are respectively measured three times. An arithmetic mean value of a total of six times is adopted as an evaluation value.

Examples of the polymerizable compound include compounds used in the following Examples, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A, but the present invention is not construed as being limited thereto.

With respect to the total solid content of the composition for forming a pattern, a content of the polymerizable compound is preferably 30% by mass or greater, more preferably 45% by mass or greater, still more preferably 50% by mass or greater, and even more preferably 55% by mass or greater, and may be 60% by mass or more or further 70% by mass or more. In addition, the upper limit value thereof is preferably lower than 99% by mass and more preferably 98% by mass or lower, and can also be 97% by mass or lower.

It is preferable that a boiling point of the polymerizable compound is set and designed on formulation in relation to the curable main agent included in the above-described composition for forming an interlayer. The boiling point of the polymerizable compound is preferably 500° C. or lower, more preferably 450° C. or lower, and still more preferably 400° C. or lower. The lower limit value thereof is preferably 200° C. or higher, more preferably 220° C. or higher, and still more preferably 240° C. or higher.

[Other Components]

The composition for forming a pattern may contain an additive other than the polymerizable compound. A polymerization initiator, a solvent, a surfactant, a sensitizer, a mold release agent, an antioxidant, a polymerization inhibitor, and the like may be contained as other additives.

Specific examples of the composition for forming a pattern, which can be used in the present invention, include the compositions described in JP2013-036027A, JP2014-090133A, and JP2013-189537A, the contents of which are incorporated in the present specification. In addition, also regarding preparation of the composition for forming a pattern and a pattern producing method, reference can be made to the descriptions in the above-described publications, the contents of which are incorporated in the present specification.

In the present invention, a content of the solvent in the composition for forming a pattern is preferably 5% by mass or lower, more preferably 3% by mass or lower, and still more preferably 1% by mass or lower with respect to the total mass of the composition for forming a pattern. The lower limit of the above-described content of the solvent is not limited, and may be 0% by mass.

In addition, the high-molecular-weight polymerizable compound is used as the polymerizable compound in the composition for forming a pattern, an aspect in which the content of the solvent is 30% by mass or greater with respect to the total mass of the composition for forming a pattern is also preferable. The above-described content thereof is preferably 50% by mass or greater and more preferably 60% by mass or greater.

Examples of the solvent contained in the composition for forming a pattern include the solvents exemplified as the solvent for an interlayer, which contained in the above-described composition for forming an interlayer, and a preferred aspect thereof is also the same.

The composition for forming a pattern may also be an aspect in which a high-molecular-weight compound is not substantially contained.

Specifically, it is preferable that a compound having a molecular weight (in a case of having a molecular weight distribution, a weight-average molecular weight) of 2,000 or more is not substantially contained, and it is more preferable that a compound having a molecular weight (in a case of having a molecular weight distribution, a weight-average molecular weight) of 1,000 or more is not substantially contained.

The fact that the high-molecular-weight compound is not substantially contained means that, for example, the content of the high-molecular-weight compound is 0.01% by mass or lower with respect to the composition for forming a pattern, and it is preferable that the content thereof is 0.005% by mass or lower and it is more preferable that the high-molecular-weight compound is not contained at all.

—Physical property value and the like—

A viscosity of the composition for forming a pattern is preferably 20.0 mPa·s or lower, more preferably 15.0 mPa·s or lower, still more preferably 11.0 mPa·s or lower, and even more preferably 9.0 mPa·s or lower. The lower limit value of the above-described viscosity is not particularly limited, but can be, for example, 5.0 mPa·s or greater. The viscosity can be measured by a known method, and for example, is measured according to the following method.

The viscosity is measured using an E-type rotational viscometer RE85L manufactured by TOKI SANGYO CO., LTD. and a standard cone rotor (1° 34′×R²⁴) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

A surface tension (γResist) of the composition for forming a pattern is preferably 28.0 mN/m or greater and more preferably 30.0 mN/m or greater, and may be 32.0 mN/m or greater. By using the composition which has high surface tension, a capillary force is increased, and the composition can be filled into a mold pattern at high speed. The upper limit value of the surface tension is not particularly limited, but from the viewpoint of relation to the interlayer and of imparting ink jet suitability, is preferably 40.0 mN/m or lower and more preferably 38.0 mN/m or lower, and may be 36.0 mN/m or lower.

The surface tension of the composition for forming a pattern is measured according to the same method as the measuring method for the alkylene glycol compound.

An Ohnishi parameter of the composition for forming a pattern is preferably 5.0 or less, more preferably 4.0 or less, and still more preferably 3.7 or less. The lower limit value of the Ohnishi parameter of the composition for forming a pattern is not particularly specified, but may be, for example, 1.0 or more or further 2.0 or more.

For the solid content of the composition for forming a pattern, the Ohnishi parameter can be determined by substituting the number of carbon atoms, the number of hydrogen atoms, and the number of oxygen atoms in all the constituent components into the following expression, respectively.

Ohnishi parameter=Sum of number of carbon atoms, number of hydrogen atoms, and number of oxygen atoms/(Number of carbon atoms−Number of oxygen atoms)

[Preservation Container]

As a storage container of the composition for forming an interlayer and the composition for forming a pattern, which are used in the present invention, storage containers known in the related art can be used. Moreover, as the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

<Base Material>

A material of the base material is not particularly specified, and reference can be made to the description in paragraph 0103 of JP2010-109092A, the contents of which are incorporated in the present specification. In the present invention, examples thereof include a silicon base material, a glass base material, a quartz base material, a sapphire base material, a silicon carbide base material, a gallium nitride base material, an aluminum base material, an amorphous aluminum oxide base material, a polycrystalline aluminum oxide base material, spin-on carbon (SOC), spin-on glass (SOG), silicon nitride, silicon oxynitride, and a base material composed of GaAsP, GaP, AlGaAs, InGaN, GaN, AlGaN, ZnSe, AlGa, InP, or ZNo. Furthermore, specific examples of a material for the glass base material include aluminosilicate glass, aluminoborosilicate glass, and barium borosilicate glass. In the present invention, a silicon base material or a base material on which an spin-on carbon (SOC) layer is formed is preferable.

As the base material, it is preferable to use a plate-shaped base material (also referred to as a “substrate”).

As the silicon base material, a surface-modified silicon base material can be appropriately used, and a silicon base material in which the carbon content in the region from the surface of the base material to the thickness of 10 nm (more preferably, the thickness of 100 nm) is 70% by mass or greater (preferably, 80% to 100% by mass) may be used. Examples thereof include a base material which has a spin-on carbon (SOC) film having a film thickness of 200 nm and is obtained by applying various spin-on carbon films to a silicon base material by a spin coating method and performing baking at 240° C. for 60 seconds. In recent years, stable mold patterning has been required even on the surfaces of such various SOC base materials, and according to the present invention, favorable adhesiveness between such a base material and a layer formed of the composition for forming an interlayer can be ensured, and stable mold patterning which prevents the base material from peeling off is achieved.

In the present invention, it is preferable to use a base material having an organic layer as an outermost layer.

Examples of the organic layer of the base material include an amorphous carbon film formed by chemical vapor deposition (CVD), and a spin-on carbon film formed by dissolving a high-carbon material in an organic solvent and performing spin coating. Examples of the spin-on carbon film include a nortricyclene copolymer, a hydrogenated naphthol novolac resin, a naphthol dicyclopentadiene copolymer, a phenol dicyclopentadiene copolymer, the fluorene bisphenol novolac described in JP2005-128509A, the acenaphthylene copolymerization described in JP2005-250434A, an indene copolymer, the fullerene having a phenol group described in JP2006-227391A, a bisphenol compound and a novolac resin thereof, a dibisphenol compound and a novolac resin thereof, a novolac resin of an adamantane phenol compound, a hydroxyvinylnaphthalene copolymer, the bisnaphthol compound and the novolac resin thereof described in JP2007-199653A, and resin compounds shown in ROMP and a tricyclopentadiene copolymerized substance.

For examples of the SOC, reference can be made to the description in paragraph 0126 of JP2011-164345A, the contents of which are incorporated in the present specification.

A contact angle of the surface of the base material to water is preferably 20° or higher, more preferably 40° or higher, and still more preferably 60° or higher. The upper limit thereof is preferably 90° or lower. The contact angle is measured according to a method described in Examples described later.

In the present invention, it is also preferable to use a base material (hereinafter, referred to as a basic base material) having a basic layer as an outermost layer. Examples of the basic base material include a base material containing a basic organic compound (for example, an amine-based compound, an ammonium-based compound, or the like), and an inorganic base material containing a nitrogen atom.

(Method for Producing Laminate)

The method for producing a laminate according to the embodiment of the present invention includes a step of applying, onto the base material, the composition for forming an interlayer, which is obtained by the method for producing a composition for forming an interlayer according to the embodiment of the present invention.

The laminate is a laminate including the base material and the interlayer formed of the above-described composition for forming an interlayer.

An undercoat layer, a closely adhesive layer, or the like other than the interlayer may be formed on the surface of the base material.

A method for applying the composition for forming an interlayer onto the surface of the base material is not particularly specified, and generally known application methods can be adopted. Specific examples of the application method include a dip coating method, an air knife coating method, a curtain coating method, a wire bar coating method, a gravure coating method, an extrusion coating method, a spin coating method, a slit scanning method, and an ink jet method, and a spin coating method is preferable.

In addition, after the composition for forming an interlayer is applied in a layered manner onto the base material, it is preferable that the solvent is volatilized (dried) by heat to form the interlayer which is a thin film.

A thickness of the interlayer is preferably 2 nm or greater, more preferably 3 nm or greater, and still more preferably 4 nm or greater, and may be 5 nm or greater, 7 nm or greater, or 10 nm or greater. Moreover, the thickness of the interlayer is preferably 40 nm or lower, more preferably 30 nm or lower, still more preferably 20 nm or lower, and may be 15 nm or lower. By setting the film thickness to be equal to or greater than the above-described lower limit value, extendability (wettability) of the composition for forming a pattern on the interlayer is improved, and it is possible to form a residual film in a nearly uniform state after imprinting. By setting the film thickness to be equal to or less than the above-described upper limit value, the thickness of the residual film after imprinting is reduced, the film thickness unevenness is less likely to occur, and thus uniformity of the residual film tends to be improved.

A surface free energy of the interlayer is preferably 30 mN/m or greater, more preferably 40 mN/m or greater, and still more preferably 50 mN/m or greater. The upper limit thereof is preferably 200 mN/m or greater, more preferably 150 mN/m or greater, and still more preferably 100 mN/m or greater.

The surface free energy can be measured at 23° C. using a surface tensiometer SURFACE TENS-IOMETER CBVP-A3 manufactured by Kyowa Interface Science Co., LTD. and a glass plate.

(Imprint Pattern Producing Method)

The imprint pattern producing method according to the embodiment of the present invention includes:

a curable layer-forming step of applying a composition for forming a pattern onto a member to be applied, which is selected from the group consisting of a laminate obtained by the method for producing a laminate according to the embodiment of the present invention and a mold;

a contact step of contacting a member which is not selected as the member to be applied from the group consisting of the laminate and the mold with the composition for forming a pattern as a contact member;

a curing step of forming the composition for forming a pattern into a cured substance; and

a peeling step of peeling off the mold from the cured substance.

[Curable Layer-Forming Step]

The imprint pattern producing method according to the embodiment of the present invention includes a curable layer-forming step of applying the composition for forming a pattern onto a member to be applied, which is selected from the group consisting of the laminate according to the embodiment of the present invention and a mold.

In the curable layer-forming step, one member selected from the group consisting of the laminate and the mold is selected as the member to be applied, and the composition for forming a pattern is applied to the selected member to be applied.

Among the laminate and the mold, one is selected as the applied member and the other is a contact member.

That is, in the curable layer-forming step, the composition for forming a pattern may be applied to the laminate and then brought into contact with the mold, or may be applied to the mold and then brought into contact with the laminate.

—Laminate—

It is sufficient that the laminate is the laminate according to the embodiment of the present invention, and it is more preferable that the laminate is obtained by the above-described interlayer-forming step.

The above-described laminate may further include a liquid film on a surface of the interlayer opposite to the base material.

The liquid film is preferably a liquid film formed by applying a composition for forming a liquid film, which will be described later, to the interlayer.

—Mold—

In the present invention, the mold is not particularly limited. Regarding the mold, reference can be made to the description in paragraphs 0105 to 0109 of JP2010-109092A (the corresponding US application is the specification of US2011/0199592A), the contents of which are incorporated in the present specification. As the mold used in the present invention, a quartz mold is preferable. A pattern (line width) of the mold used in the present invention preferably has a size of 50 nm or less. The pattern of the mold can be formed according to a desired processing accuracy, for example, by photolithography, an electron beam drawing method, or the like, but in the present invention, a mold pattern producing method is not particularly limited.

—Application Method—

A method for applying the composition for forming a pattern to the member to be applied is not particularly specified, and generally known application methods can be adopted. Examples thereof include a dip coating method, an air knife coating method, a curtain coating method, a wire bar coating method, a gravure coating method, an extrusion coating method, a spin coating method, a slit scanning method, and an ink jet method.

Among them, preferred examples thereof include an ink jet method and a spin coating method.

In addition, the composition for forming a pattern may be applied through multiple applying.

In a method of arranging liquid droplets by the ink jet method, a volume of the liquid droplets is preferably approximately 1 to 20 pL, and the liquid droplets are preferably arranged on the surface of the base material at an interval between the liquid droplets. The interval between the liquid droplets may be appropriately set according to the volume of the liquid droplets, and is preferably an interval of 10 to 1,000 μm. In a case of the ink jet method, the interval between liquid droplets is an arrangement interval between ink jet nozzles.

The ink jet method has an advantage that a loss of the composition for forming a pattern is small.

Specific examples of the method for applying the composition for forming a pattern by the ink jet method include the methods described in JP2015-179807A, WO2016/152597A, and the like, and the methods described in these documents can also be suitably used in the present invention.

On the other hand, the spin coating method has an advantage that the coating process is highly stable and the choice of materials which can be used is expanded.

Specific examples of the method for applying the composition for forming a pattern by the spin coating method include the methods described in JP2013-095833A, JP2015-071741A, and the like, and the methods described in these documents can also be suitably used in the present invention.

—Drying Step—

Moreover, the imprint pattern producing method according to the embodiment of the present invention may further include a drying step of drying the composition for forming a pattern according to the embodiment of the present invention applied in the applying step.

In particular, in a case where a composition including a solvent is used as the composition for forming a pattern, it is preferable that the imprint pattern producing method according to the embodiment of the present invention includes the drying step.

In the drying step, at least a part of the solvent included in the composition for forming a pattern applied is removed.

A drying method is not particularly limited, and drying by heating, drying by blowing air, or the like can be used without particular limitation, but drying by heating is preferable.

A heating unit is not particularly limited, and a well-known hot plate, oven, infrared heater, or the like can be used.

In the present invention, a layer formed from the composition for forming a pattern after the applying step and the drying step performed as necessary and before the contact step is also referred to as a “pattern forming layer”.

[Contact Step]

The imprint pattern producing method according to the embodiment of the present invention includes a contact step of contacting a member which is not selected as the member to be applied from the group consisting of the laminate and the mold with the composition for forming a pattern (pattern forming layer) as a contact member.

In a case where the laminate is selected as the member to be applied in the above-described applying step, in the contact step, the mold, which is the contact member, is brought into contact with the surface of the laminate to which the composition for forming a pattern is applied (surface on which the pattern forming layer is formed).

In a case where the mold is selected as the member to be applied in the above-described applying step, in the contact step, a surface of the laminate on which the interlayer is formed, which is the contact member, is brought into contact with the surface of the mold to which the composition for forming a pattern is applied (surface on which the pattern forming layer is formed).

That is, in a case where the mold is selected as the member to be applied in the above-described applying step, by the contact step, the interlayer according to the present invention exists between the base material and the curable layer (the pattern forming layer after the contact step).

Details of the laminate and the mold are as described above.

In a case where the composition for forming a pattern according to the present invention (pattern forming layer) which is applied to the applied member is brought into contact with the contact member, a pressing pressure is preferably 1 MPa or lower. By setting the pressing pressure to 1 MPa or lower, the laminate or the mold is less likely to be deformed and thus the pattern accuracy tends to be improved. Moreover, also from the viewpoint that a device tends to be miniaturized due to low pressing force, the above-described range is preferable.

In addition, it is also preferable that the contact between the pattern forming layer and the contact member is performed under an atmosphere including a helium gas, a condensable gas, or both a helium gas and a condensable gas.

[Curing Step]

The imprint pattern producing method according to the embodiment of the present invention includes a curing step of forming a cured substance with the composition for forming a pattern.

The curing step is performed after the above-described contact step and before the above-described peeling step.

Examples of a curing method include curing by heating and curing by exposure, which may be determined according to the type of the polymerization initiator included in the composition for forming a pattern, and curing by exposure is preferable.

For example, in a case where the above-described polymerization initiator is a photopolymerization initiator, the composition for forming a pattern can be cured by performing exposure in the curing step.

An exposure wavelength is not particularly limited, and may be determined according to the polymerization initiator. For example, ultraviolet light or the like can be used.

An exposure light source may be determined according to the exposure wavelength, and examples thereof include g-rays (wavelength: 436 nm), h-rays (wavelength: 405 nm), i-rays (wavelength: 365 nm), broadband light (light including at least two wavelengths of light selected from the group consisting of three wavelengths of g-rays, h-rays, and i-rays, and light having a wavelength shorter than that of i-rays; examples thereof include a high-pressure mercury lamp in a case where an optical filter is not used), semiconductor laser (wavelength: 830 nm, 532 nm, 488 nm, 405 nm, and the like), metal halide lamp, excimer laser, KrF excimer laser (wavelength: 248 nm), ArF excimer laser (wavelength: 193 nm), F₂ excimer laser (wavelength: 157 nm), extreme ultraviolet rays (EUV; wavelength: 13.6 nm), and electron beam.

Among them, preferred examples thereof include exposure using i-rays or broadband light.

An irradiation amount (exposure amount) during the exposure may be sufficiently larger than the minimum irradiation amount required for curing the composition for forming a pattern. The irradiation amount required for curing the composition for forming a pattern can be appropriately determined by examining consumption or the like of an unsaturated bond of the composition for forming a pattern.

The exposure amount is, for example, preferably in a range of 5 to 1,000 mJ/cm² and more preferably in a range of 10 to 500 mJ/cm².

An exposure illuminance is not particularly limited and may be selected depending on a relationship with the light source, but is preferably in a range of 1 to 500 mW/cm² and more preferably in a range of 10 to 400 mW/cm².

An exposure time is not particularly limited and may be determined in consideration of the exposure illuminance according to the exposure amount, but is preferably 0.01 to 10 seconds and more preferably 0.5 to 1 second.

A temperature of the base material during the exposure is usually room temperature, but in order to increase reactivity, the exposure may be performed while heating. Since setting a vacuum state as a stage prior to the exposure is effective in preventing air bubbles from being mixed, suppressing a decrease in reactivity due to oxygen mixing, and improving adhesiveness between the mold and the composition for forming a pattern, the light irradiation may be performed in a vacuum state. Moreover, a preferred degree of vacuum during the exposure is in a range of 10⁻¹ Pa to normal pressure.

After the exposure, as necessary, the composition for forming a pattern after the exposure may be heated. A heating temperature is preferably 150° C. to 280° C. and more preferably 200° C. to 250° C. Moreover, a heating time is preferably 5 to 60 minutes and more preferably 15 to 45 minutes.

In addition, in the curing step, only the heating step may be performed without exposure. For example, in a case where the above-described polymerization initiator is a thermal polymerization initiator, the composition for forming a pattern can be cured by performing heating in the curing step. A preferred aspect of the heating temperature and heating time in this case is the same as in the heating temperature and heating time in the case of heating after the above-described exposure.

A heating unit is not particularly limited, and examples thereof include the same heating unit as in the heating of the above-described drying step.

[Peeling Step]

The imprint pattern producing method according to the embodiment of the present invention includes a peeling step of peeling off the cured substance from the mold.

By the peeling step, the cured substance obtained in the curing step is peeled off from the mold, and a cured substance in a patterned shape (also referred to as a “cured substance pattern”) to which the pattern of the mold is transferred can be obtained. The obtained cured substance pattern can be used for various uses as described later. In the present invention, the imprint pattern producing method is particularly advantageous in that a fine cured substance pattern of a nano order can be formed, and a cured substance pattern having a size of 50 nm or lower and particularly 30 nm or lower can also be formed. The lower limit value of the size of the above-described cured substance pattern is not particularly specified, but can be, for example, 1 nm or greater.

A peeling method is not particularly limited, and for example, the peeling can be performed by using a mechanical release device or the like known in the imprint pattern producing method.

(Method for Manufacturing Device)

A method for manufacturing a device according to an embodiment of the present invention includes the imprint pattern producing method according to the embodiment of the present invention.

Specifically, a pattern (cured substance pattern) formed by the imprint pattern producing method according to the embodiment of the present invention can be used in a method for manufacturing a device such as a permanent film used in a liquid crystal display device (LCD) or the like, or an etching resist (mask for lithography) for manufacturing a semiconductor element.

In particular, the present invention describes a method for manufacturing a circuit board, which includes a step of obtaining a pattern (cured substance pattern) by the imprint pattern producing method according to the embodiment of the present invention, and a method for manufacturing a device including the circuit board. The method for manufacturing a circuit board according to the preferred embodiment of the present invention may further include a step of performing etching or ion implantation on the substrate using the pattern (cured substance pattern) obtained by the above-described pattern forming method as a mask and a step of forming an electronic member. The above-described circuit board is preferably a semiconductor element. That is, the present invention describes a method for manufacturing a semiconductor device, including the imprint pattern producing method according to the embodiment of the present invention. Further, the present invention describes a method for manufacturing a device, which includes a step of obtaining a circuit board by the above-described method for manufacturing a circuit board and a step of connecting the circuit board and a control mechanism which controls the circuit board.

Moreover, by forming a grid pattern on a glass base material of a liquid crystal display device using the imprint pattern producing method according to the embodiment of the present invention, a polarizing plate having low reflection or absorption and a large screen size (for example, 55 inches, or greater than 60 inches) can be manufactured at a low cost. That is, the present invention describes a method for manufacturing a polarizing plate and a method for manufacturing a device including the polarizing plate, which include the imprint pattern producing method according to the embodiment of the present invention. For example, the polarizing plate described in JP2015-132825A or WO2011/132649A can be manufactured. Furthermore, 1 inch is 25.4 mm.

The pattern (cured substance pattern) manufactured by the imprint pattern producing method according to the embodiment of the present invention is also useful as an etching resist (mask for lithography). That is, the present invention describes a method for manufacturing a device in which the obtained cured substance pattern is used as an etching resist, including the imprint pattern producing method according to the embodiment of the present invention.

In a case where the cured substance pattern is used as an etching resist, examples thereof include an aspect in which, first, a pattern (cured substance pattern) is formed by applying the imprint pattern producing method according to the embodiment of the present invention on a base material, and the obtained cured substance pattern is used as an etching mask to etch the base material. By performing etching with an etching gas such as hydrogen fluoride or the like in a case of wet etching and CF₄ or the like in a case of dry etching, a pattern can be formed on the base material along the shape of the desired cured substance pattern.

Moreover, the pattern (cured substance pattern) produced by the imprint pattern producing method according to the embodiment of the present invention can be also preferably used for producing a recording medium such as a magnetic disc, a light-receiving element such as a solid-state imaging element, a light emitting element such as a light emitting diode (LED) and organic electroluminescence (organic EL), an optical device such as a liquid crystal display device (LCD), an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, a photonic liquid crystal, or a guide pattern for fine pattern formation (directed self-assembly, DSA) using self-assembly of block copolymers.

That is, the present invention describes a method for manufacturing these device, including the imprint pattern producing method according to the embodiment of the present invention.

<Composition for Forming Liquid Film>

In addition, in the present invention, it is also preferable that a liquid film is formed on the interlayer by using a composition for forming a liquid film containing a radically polymerizable compound which is a liquid at 23° C. and 1 atm. In the present invention, the liquid film can be obtained by applying the composition for forming a liquid film to the interlayer and then drying the composition, in the same manner as the composition for forming a pattern. By forming such a liquid film, there are effects that the adhesiveness between the interlayer and the composition for forming a pattern is further improved, and that the wettability of the composition for forming a pattern on the interlayer is also improved. Hereinafter, the composition for forming a liquid film will be described.

A viscosity of the composition for forming a liquid film is preferably 1,000 mPa·s or lower, more preferably 800 mPa·s or lower, still more preferably 500 mPa·s or lower, and even more preferably 100 mPa·s or lower. The lower limit value of the viscosity is not particularly limited, but can be, for example, 1 mPa·s or greater. The viscosity is measured according to the following method.

The viscosity is measured using an E-type rotational viscometer RE85L manufactured by TOKI SANGYO CO., LTD. and a standard cone rotor (1° 34′×R²⁴) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

[Radically Polymerizable Compound A]

The composition for forming a liquid film contains a radically polymerizable compound (radically polymerizable compound A) which is a liquid at 23° C. and 1 atm.

A viscosity of the radically polymerizable compound A at 23° C. is preferably 1 to 100,000 mPa·s. The lower limit thereof is preferably 5 mPa·s or greater and more preferably 11 mPa·s or greater. The upper limit thereof is preferably 1,000 mPa·s or lower and more preferably 600 mPa·s or lower.

The radically polymerizable compound A may be a monofunctional radically polymerizable compound having only one radically polymerizable group in one molecule, or a polyfunctional radically polymerizable compound having two or more radically polymerizable groups in one molecule. The monofunctional radically polymerizable compound and the polyfunctional radically polymerizable compound may be used in combination. Among them, for a reason of suppressing pattern collapse, the radically polymerizable compound A contained in the composition for forming a liquid film preferably includes a polyfunctional radically polymerizable compound, more preferably includes a radically polymerizable compound having two to five radically polymerizable groups in one molecule, still more preferably includes a radically polymerizable compound having two to four radically polymerizable groups in one molecule, and particularly preferably includes a radically polymerizable compound having two radically polymerizable groups in one molecule.

Furthermore, the radically polymerizable compound A preferably contains at least one of an aromatic ring (the number of carbon atoms is preferably 6 to 22, more preferably 6 to 18, and still more preferably 6 to 10) or an alicyclic ring (the number of carbon atoms is preferably 3 to 24, more preferably 3 to 18, and still more preferably 3 to 6), and more preferably contains an aromatic ring. The aromatic ring is preferably a benzene ring. Moreover, a molecular weight of the radically polymerizable compound A is preferably 100 to 900.

Examples of the radically polymerizable group of the radically polymerizable compound A include ethylenically unsaturated bond-containing groups, such as a vinyl group, an allyl group, and a (meth)acryloyl group, and a (meth)acryloyl group is preferable.

It is also preferable that the radically polymerizable compound A is a compound represented by Formula (I-1).

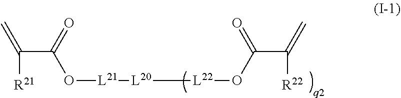

L²⁰ is a (1+q2)-valent linking group, and examples thereof include (1+q2)-valent linking groups which contain a group (the number of carbon atoms is preferably 1 to 12, more preferably 1 to 6, and still more preferably 1 to 3) having an alkane structure, a group (the number of carbon atoms is preferably 2 to 12, more preferably 2 to 6, and still more preferably 2 or 3) having an alkene structure, a group (the number of carbon atoms is preferably 6 to 22, more preferably 6 to 18, and still more preferably 6 to 10) having an aryl structure, a group (the number of carbon atoms is preferably 1 to 22, more preferably 1 to 18, and still more preferably 1 to 10, examples of a heteroatom include a nitrogen atom, a sulfur atom, and an oxygen atom, and a 5-membered ring, a 6-membered ring, or a 7-membered ring are preferable) having a heteroaryl structure, or a group obtained by combining these groups. Examples of the group in which two aryl groups are combined include groups having a structure such as biphenyl, diphenylalkane, biphenylene, and indene. Examples of a combination of the group having a heteroaryl structure and the group having an aryl structure include groups having a structure such as indole, benzimidazole, quinoxaline, and carbazole.

L²⁰ is preferably a linking group including at least one kind selected from a group having an aryl structure or a group having a heteroaryl structure, and more preferably a linking group including a group having an aryl structure.

R²¹ and R²² each independently represent a hydrogen atom or a methyl group.

L²¹ and L²² each independently represent a single bond or the linking group L, and a single bond or an alkylene group is preferable.

L²⁰ and L²¹ or L²² may be bonded to each other through or without through the linking group L to form a ring. L²⁰, L²¹, and L²² may have the above-described substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, still more preferably 0 or 1, and particularly preferably 1.

As the radically polymerizable compound A, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A can also be used.

A content of the radically polymerizable compound A in the composition for forming a liquid film is preferably 0.01% by mass or greater, more preferably 0.05% by mass or greater, and still more preferably 0.1% by mass or greater. The upper limit thereof is preferably 10% by mass or lower, more preferably 5% by mass or lower, and still more preferably 1% by mass or lower.

The content of the radically polymerizable compound A in the solid content of the composition for forming a liquid film is preferably 50% by mass or greater, more preferably 75% by mass or greater, and still more preferably 90% by mass or greater. The upper limit thereof may be 100% by mass. The radically polymerizable compound A may be used alone or in combination of two or more kinds thereof. In a case where two or more kinds thereof are used, the total amount thereof is preferably within the above-described range.

Furthermore, it is also preferable that the solid content of the composition for forming a liquid film substantially consists of the radically polymerizable compound A. The case where the solid content of the composition for forming a liquid film substantially consists of the radically polymerizable compound A means that the content of the radically polymerizable compound A in the solid content of the composition for forming a liquid film is 99.9% by mass or greater, the content is more preferably 99.99% by mass or greater, and it is still more preferable that the solid content consists of the radically polymerizable compound A.

[Solvent]

The composition for forming a liquid film preferably contains a solvent (hereinafter, referred to as a “solvent for a liquid film” in some cases). Examples of the solvent for a liquid film include the solvents described in the above-described section of the solvent for an interlayer, and these solvents can be used. A content of the solvent for a liquid film in the composition for forming a liquid film is preferably 90% by mass or greater and more preferably 99% by mass or greater, and may be 99.99% by mass or greater.

A boiling point of the solvent for a liquid film is preferably 230° C. or lower, more preferably 200° C. or lower, still more preferably 180° C. or lower, even more preferably 160° C. or lower, and further still more preferably 130° C. or lower. The lower limit value thereof is preferably 23° C. or higher and more preferably 60° C. or higher. By setting the boiling point within the above-described range, the solvent can be easily removed from the liquid film, which is preferable.

[Radical Polymerization Initiator]

The composition for forming a liquid film may contain a radical polymerization initiator. Examples of the radical polymerization initiator include a thermal radical polymerization initiator and a photoradical polymerization initiator, and a photoradical polymerization initiator is preferable. As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound, a hexaarylbiimidazole compound, an oxime compound, an organic peroxide, a thio compound, a ketone compound, an aromatic onium salt, an acetophenone compound, an azo compound, an azide compound, a metallocene compound, an organic boron compound, and an iron arene complex. For the details thereof, reference can be made to the description in paragraphs 0165 to 0182 of JP2016-027357A, the contents of which are incorporated in the present specification. Among them, an acetophenone compound, an acylphosphine compound, or an oxime compound is preferable. Examples of a commercially available product thereof include IRGACURE OXE01, IRGACURE OXE02, IRGACURE 127, IRGACURE 819, IRGACURE 379, IRGACURE 369, IRGACURE 754, IRGACURE 1800, IRGACURE 651, IRGACURE 907, IRGACURE TPO, and IRGACURE 1173 (all manufactured by BASF SE), and Omnirad 184, Omnirad TPO H, Omnirad 819, and Omnirad 1173 (all manufactured by IGM Resins B.V.).

In a case where the radical polymerization initiator is contained, the content thereof with respect to the solid content of the composition for forming a liquid film is preferably 0.1% to 10% by mass, more preferably 1% to 8% by mass, and still more preferably 2% to 5% by mass. In a case where two or more kinds of the radical polymerization initiators are used, the total amount thereof is preferably within the above-described range.

[Other Components]

The composition for forming a liquid film may include one kind or two or more kinds of a polymerization inhibitor, an antioxidant, a leveling agent, a thickener, a surfactant, or the like, in addition to the above-described components.

### EXAMPLES

Hereinafter, the present invention will be described in more detail with reference to Examples. The materials, the used amounts, the proportions, the treatment details, the treatment procedures, and the like shown in the following Examples can be appropriately modified without departing from the spirit of the present invention. Therefore, the scope of the present invention is not limited to the specific examples described below. In Examples, unless otherwise specified, “parts” and “%” are based on mass, and an environmental temperature (room temperature) in each step is 23° C.

<Preparation of Precursor Composition 1>

In each of Examples and Comparative Examples, each component shown in the tables below was mixed to prepare a precursor composition 1 or a comparative precursor composition 1.

The content of each component was the content (part by mass) described in the column of “Content” in the tables below.

In the tables, it means that a component described as “Not added” is not contained.

In the tables, the description of “B-1/B-2 (90/10)” or the like indicates that B-1 and B-2 were used in a mass ratio of B-1:B-2=90:10. Moreover, in the above description, the total content of B-1 and B-2 is the value described in the column of “Content”).

<First Filtering Step>

In each of Examples and Comparative Examples, each of the obtained precursor composition 1 or the comparative precursor composition 1 was filtered through a filter described in the column of “Filter” in “First filtering step” in the tables below.

A filtration speed was set to a speed (cm/min) described in the column of “cm/min” in “First filtering step” in the tables below.

In the example in which “Not performed” is described in the above-described column of “Filter”, the first filtering step was not performed. A proportion of the total solid content to the total mass of the precursor composition 1 is described in the column of “Concentration of solid contents” of the precursor composition 1. The unit is (%).

<Preparation of Precursor Composition 2 (Preparing Step)>

In each of Examples and Comparative Examples, a solvent was added to the precursor composition 1 or the comparative precursor composition 1 after the first filtering step (however, in the example in which “Not performed” is described in the above-described column of “Filter” in “First filtering step” in the tables, a composition not subjected to the first filtering step after preparation) to prepare a precursor composition 2 in which a content ratio (mass ratio) of each component was the content ratio described in the column of “Precursor composition 2” in the tables. A proportion of the total solid content to the total mass of the precursor composition 2 is described in the column of “Concentration of solid contents” of the precursor composition 2. The unit is (%).

<Second Filtering Step>

In each of Examples and Comparative Examples, each of the obtained precursor composition 2 or the comparative precursor composition 2 was filtered through a filter described in the column of “Filter” in “Second filtering step” in the tables below to obtain a composition for forming an interlayer for nanoimprint. A proportion of the total solid content to the total mass of the composition for forming an interlayer for nanoimprint was the same as the value described in the column of “Concentration of solid contents” of the precursor composition 2.

A filtration speed was set to a speed (cm/min) described in the column of “cm/min” in “Second filtering step” in the tables below.

In the tables, the description of “IonKleen™ SL+IonKleen™ AN” in the column of “Filter” means that IonKleen™ SL and IonKleen™ AN were used in series and the filtration was performed by a filter in the order of IonKleen™ AN and IonKleen™ SL.

<Third Filtering Step>

In the example in which “Third filtering step” is described in the tables, the composition after the second filtration was further filtered through a filter described in the column of “Filter” in “Third filtering step” in the tables below to obtain a composition for forming an interlayer for nanoimprint.

| | | | | Comparative | | | | |
|---|---|---|---|---|---|---|---|---|
| | | | Example | Example | Example | Example | Example | Example |
| | | | 1 | 1 | 2 | 3 | 4 | 5 |
| Precursor | Resin | Type | P-1 | P-31 | P-2 | P-3 | P-4 | P-4 |
| composition 1 | | Content | 20 | 20 | 20 | 20 | | 20 |
| | Polymerization | Type | A-1 | A-1 | A-1 | A-12 | A-1 | A-1 |
| | inhibitor | Content | 0.02 | 0.02 | 0.00002 | 0.02 | 0.02 | 0.02 |
| | Additive | Type | B-1/ | Not added | Not added | Not added | Not added | Not added |
| | | | B-2 | | | | | |
| | | | (90/10) | | | | | |
| | | Content | 0.1 | 0 | 0 | 0 | 0 | 0 |
| | Solvent | Type | PGMEA | PGMEA | PGMEA | PGMEA | PGMEA | PGMEA |
| | | Content | 79.88 | 79.98 | 79.99998 | 79.98 | 79.98 | 79.98 |
| | Concentration of solid | | 20.12 | 20.02 | 20.00002 | 20.02 | 20.02 | 20.02 |
| | contents | | | | | | | |
| First filtering step | | Filter | No. 2 | Not | No. 2 | No. 2 | No. 2 | Purasol ™ |
| | | | | performed | | | | SP |
| | | [symbol] | 47.2 | 0 | 47.2 | 94.4 | 4.7 | 8.8 |
| Precursor | Resin | Type | P-1 | P-31 | P-2 | P-3 | P-4 | P-4 |
| composition 2 | | Content | 0.3 | 0.3 | 0.3 | 0.3 | 0.3 | 0.3 |
| | Polymerization | Type | A-1 | A-1 | A-1 | A-12 | A-1 | A-1 |
| | inhibitor | Content | 0.0003 | 0.0003 | 0.0000003 | 0 .0003 | 0.0003 | 0.0003 |
| | Additive | Type | B-1/ | Not added | Not added | Not added | Not added | Not added |
| | | | B-2 | | | | | |
| | | | (90/10) | | | | | |
| | | Content | 0.0015 | 0 | 0 | 0 | 0 | 0 |
| | Solvent | Type | PGMEA | PGMEA | PGMEA | PGMEA | PGMEA | PGMEA |
| | | Content | 99.6982 | 94.6997 | 99.6999997 | 99.6997 | 99.6997 | 99.6997 |
| | Concentration of solid | | 0.3018 | 0.3003 | 0.3000003 | 0.3003 | 0.3003 | 0.3003 |
| | coments | | | | | | | |
| Second filtering step | | Filter | Purasol ™ | Purasol ™ | Purasol ™ | Purasol ™ | Purasol ™ | No. 2 |
| | | | SP | SP | SP | SP | SP | |
| | | [symbol] | 8.8 | 8.8 | 8.8 | 8.8 | 8.8 | 47.2 |
| Adhesiveness | | | A | C | S | A | A | A |
| Damage to mold | | | A | C | A | A | A | B |
| Adhesiveness after aging | | | A | C | S | S | A | A |
| | | | Example | Example | Example | Example | Example | Example |
| | | | 6 | 7 | 8 | 9 | 10 | 11 |
| Precursor | Resin | Type | P-4 | P-4 | P-1 | P-1 | P-5 | P-6 |
| composition 1 | | Content | 20 | 20 | 20 | 20 | 20 | 20 |
| | Polymerization | Type | A-1 | A-1 | A-1 | A-1 | A-9 | A-10 |
| | inhibitor | Content | 0.02 | 0.02 | 0.02 | 0.02 | 0.02 | 0.02 |
| | Additive | Type | Not added | Not added | Not added | Not added | Not added | Not added |
| | | Content | 0 | 0 | 0 | 0 | 0 | 0 |
| | Solvent | Type | PGMEA | PGMEA | PGMEA | PGMEA | PGMEA | PGMEA |
| | | Content | 79.98 | 79.98 | 79.98 | 79.98 | 79.98 | 79.98 |
| | Concentration of solid | | 20.02 | 20.02 | 20.02 | 20.02 | 20.02 | 20.02 |
| | contents | | | | | | | |
| First filtering step | | Filter | No. 2 | No. 2 | No. 2 | No. 2 | No. 2 | No. 2 |
| | | [symbol] | 250 | 0.1 | 47.2 | 47.2 | 47.2 | 47.2 |
| Precursor | Resin | Type | P-4 | P-4 | P-1 | P-1 | P-5 | P-6 |
| composition 2 | | Content | 0.3 | 0.3 | 0.3 | 0.3 | 0.3 | 0.3 |
| | Polymerization | Type | A-1 | A-1 | A-1 | A-1 | A-9 | A-10 |
| | inhibitor | Content | 0.0003 | 0.0003 | 0.0003 | 0.05 | 0.0003 | 0.0003 |
| | Additive | Type | Not added | Not added | Not added | Not added | Not added | Not added |
| | | Content | 0 | 0 | 0 | 0 | 0 | 0 |
| | Solvent | Type | PGMEA | PGMEA | PGMEA | PGMEA | PGMEA | PGMEA |
| | | Content | 99.0997 | 99.6997 | 99.697 | 99.65 | 99.6997 | 99.6997 |
| | Concentration of solid | | 0.3003 | 0.3003 | 0.3003 | 0.35 | 0.3003 | 0.3003 |
| | coments | | | | | | | |
| Second Filtering step | | Filter | Purasol ™ | Purasol ™ | LifeASSURE ™ | Purasol ™ | Purasol ™ | Purasol ™ |
| | | | SP | SP | | SP | SP | SP |
| | | [symbol] | 47.2 | 8.8 | 8.8 | 8.8 | 44.0 | 0.9 |

| | | | | | | |
|---|---|---|---|---|---|---|
| Adhesiveness | A | A | A | B | A | A |
| Damage to mold | B | B | B | A | A | A |
| Adhesiveness after aging | A | A | A | A | B | A |

[symbol]

indicates data missing or illegible when filed

| | | | Example | Example | Example | Example | Example | Example |
|---|---|---|---|---|---|---|---|---|
| | | | 12 | 13 | 14 | 15 | 16 | 17 |
| Precursor | Resin | Type | P-7 | P-8 | P-9 | P-10 | P-11 | P-12 |
| composition 1 | | Content | 1 | 44 | 20 | 20 | 20 | 20 |
| | Polymerization | Type | A-1 | A-1 | A-11 | A-1 | | A-13 |
| | inhibitor | Content | 0.001 | 0.844 | 0.02 | 0.02 | 0 | 0.02 |
| | Additive | Type | Not added | B-3 | B-3 | Not added | Not added | Not added |
| | | Content | 0 | 0.22 | 0.1 | 0 | 0 | 0 |
| | Solvent | Type | PGMEA | PGMEA | PGMEA | PGMEA | PGMEA | PGMEA |
| | | Content | 98.999 | 33.736 | 79.88 | 79.98 | 80 | 79.98 |
| | Concentration of solid | | 1.001 | 44.264 | 20.12 | 20.02 | 20 | 20.02 |
| | contents | | | | | | | |
| First filtering step | | Filter | No. 4A | No. 1 | No. 2 | No. 2 | No. 2 | No. 131 |
| | | [symbol] | 47.2 | 47.2 | 47.2 | 47.2 | 47.2 | 47.2 |
| | Resin | Type | P-7 | P-8 | P-9 | P-10 | P-11 | P-12 |
| | | Content | 0.3 | 0.3 | 1.0 | 0.08 | 0.3 | 0.3 |
| | Polymerization | Type | A-1 | A-1 | A-11 | A-1 | | A-13 |
| | inhibitor | Contrat | 0.0003 | 0.0003 | 0.001 | 0.00008 | 0.0003 | 0.0003 |
| | Additive | Type | Not added | B-3 | B-1 | Not added | Not added | Not added |
| | | Content | 0 | 0.0015 | 0.005 | 0 | 0 | 0 |
| | Solvent | Type | PGMEA | FGMEA | PGMEA | PGMEA | PGMEA | PGMEA |
| | | Content | 99.8997 | 99.6982 | 98.994 | 99.91992 | 99.6997 | 99.6997 |
| | Concentration of solid | | 0.3003 | 0.3018 | 1.006 | 0.08008 | 0.3003 | 0.3003 |
| | contents | | | | | | | |
| Second filtering step | | Filter | P Emflon | Purasol ™ | Purasol ™ | Purasol ™ | Purasol ™ | Purasol ™ |
| | | | | SP | SP | SP | SP | SP |
| | | [symbol] | 8.8 | 8.8 | 12.5 | 12.5 | 8.8 | 8.8 |
| Adhesiveness | | | A | A | A | A | A | A |
| Dommage to mold | | | A | A | A | A | A | B |
| Adhesiverss after aging | | | A | A | A | A | A | A |
| | | | Example | Example | Example | Example | Example | Example |
| | | | 18 | 19 | 20 | 21 | 22 | 23 |
| Precursor | Resin | Type | P-13 | P-14 | P-15 | P-16 | P-17 | P-18 |
| composition 1 | | Content | 20 | 20 | 20 | 20 | 20 | 20 |
| | Polymerization | Type | A-8 | A-14 | A-2 | A-1/A-b | | A-15 |
| | inhibitor | Content | 0.02 | 0.02 | 0.02 | 0.02/0102 | 0 | 0.02 |
| | Additive | Type | Not added | Not added | Not added | B-4 | B-2 | B-1 |
| | | Content | 0 | 0 | 0 | 0.1 | 0.1 | 0.1 |
| | Solvent | Type | PGMEA | PGMEA | PGMEA | PGMEA | PGMEA | PGMEA/PGME |
| | | | | | | | | (20/80) |
| | | Content | 79.98 | 79.98 | 79.98 | 79.86 | 79.9 | 79.88 |
| | Concentration of solid | | 20.02 | 20.02 | 20.02 | 20.14 | 20.1 | 20.12 |
| | contents | | | | | | | |
| First filtering step | | Filter | No. 2 | No. 101 | No. 2 | No. 1 | No.2 | No. 2 |
| | | [symbol] | 47.2 | 47.2 | 47.2 | 47.2 | 47.2 | 47.2 |
| | Resin | Type | P-14 | P-14 | P-15 | P-16 | P-17 | P-18 |
| | | Content | 0.3 | 0.3 | 0.3 | 0.3 | 0.3 | 0.3 |
| | Polymerization | Type | A-14 | A-14 | A-2 | A-1/A-6 | | A-15 |
| | inhibitor | Contrat | 0.003 | 0.0003 | 0.0003 | 0.0003 | 0 | 0.0003 |
| | Additive | Type | Not added | Not added | Not added | B-4 | B-2 | B-1 |
| | | Content | 0 | 0 | 0 | 0.0015 | 0.0015 | 0.0015 |
| | Solvent | Type | PGMEA | PGMEA | PGMEA | PGMEA | PGMEA | PGMEA/PGME |
| | | | | | | | | (20/80) |
| | | Content | 99.6997 | 99.6997 | 99.6997 | 99.6982 | 99.6985 | 99.6982 |
| | Concentration of solid | | 0.3003 | 0.3003 | 0.3003 | 0.3018 | 0.3015 | 0.3018 |
| | contents | | | | | | | |
| Second filtering step | | Filter | Purasol ™ | Purasol ™ | Purasol ™ | Purasol ™ | [symbol] | łonKleen ™ SL |
| | | | SP | SP | SP | SP | [symbol] | IonKleen ™ AN |
| | | [symbol] | 8.8 | 8.8 | 8.8 | 8.8 | 8.8 | 8.8 |

| | | | | | | |
|---|---|---|---|---|---|---|
| Adhesiveness | A | A | A | A | A | A |
| Dommage to mold | A | A | A | A | A | A |
| Adhesiverss after aging | A | A | A | A | A | A |

[symbol]

indicates data missing or illegible when filed

| | | | Example | Example | Example | Example | Example | Example |
|---|---|---|---|---|---|---|---|---|
| | | | 24 | 25 | 26 | 23 | 28 | 29 |
| Precursor | Resin | Type | P-19 | P-20 | P-21 | P-22 | P-23 | P-24 |
| composition 1 | | Content | 20 | 20 | 20 | 20 | 20 | 20 |
| | Polymerization | Type | A-2 | A-1 | A-3 | A-1 | A-4 | A-5 |
| | inhibitor | Content | 0.02 | 0.02 | 0.02 | 0.02 | 0.02 | 0.02 |
| | Additive | Type | Not added | B-1 | B-1 | B-1 | B-1 | B-1 |
| | | Contest | 0 | 0.1 | 0.1 | 0.1 | 0.1 | 0.1 |
| | | Type | PGMEA | PGMEA | PGMEA | PGMEA | PGMEA | PGMEA |
| | | Content | 79.98 | 79.88 | 79.88 | 79.88 | 79.88 | 79.88 |
| | Concentration of solid | | 20.02 | 20.12 | 20.12 | 20.12 | 20.12 | 20.12 |
| | contents | | | | | | | |
| First filtering step | | Filter | No. 4A | No. 2 | No. 101 | No. 2 | No. 2 | No.2 |
| | | [symbol] | 47.2 | 47.2 | 47.2 | 47.2 | 47.2 | 47.2 |
| Precursor | Resin | Type | P-19 | P-20 | P-21 | P-22 | P-23 | P-24 |
| composition 2 | | Content | 0.3 | 0.3 | 0.3 | 0.3 | 0.3 | 0.3 |
| | Polymerization | Type | A-2 | A-1 | A-3 | A-1 | A-4 | A-5 |
| | inhibitor | Content | 0.0003 | 0.0003 | 0.0003 | 0.0003 | 0.0003 | 0.0003 |
| | Additive | Type | Not added | B-1 | B-1 | B-1 | B-1 | B-1 |
| | | Content | 0 | 0.0015 | 0.0015 | 0.0015 | 0.0015 | 0.0015 |
| | Solvent | Type | PGMEA | PGMEA | PGMEA | PGMEA | PGMEA | PGMEA |
| | | Content | 99.6997 | 99.6982 | 99.6982 | 99.6982 | 99.6982 | 99.6982 |
| | Concentration of sold. | | 0.3003 | 0.3018 | 0.3018 | 0.3018 | 0.3018 | 0.3018 |
| | contents | | | | | | | |
| Second filtering step | | Filter | Purasol ™ | Purasol ™ | PE-Kleen | Purasol ™ | [symbol] N66 | [symbol] |
| | | | SN | SP | | SP | | P-Nylon |
| | | [symbol] | 8.8 | 8.8 | 8.8 | 8.8 | 8.8 | 8.8 |
| Adhesiveness | | | A | A | A | A | A | A |
| Damage to mold | | | A | A | A | A | A | A |
| Adhesiveness after aging | | | A | A | A | A | A | A |
| | | | Example | Example | Example | Example | Example | Example |
| | | | 30 | 31 | 32 | 33 | 34 | 35 |
| Precursor | Resin | Type | P-25 | P-26 | P-27 | P-28 | P-29 | P-30 |
| composition 1 | | Content | 20 | 20 | 20 | 20 | 20 | 20 |
| | Polymerization | Type | A-1 | A-7 | A-1 | A-6 | A-8 | A-1 |
| | inhibitor | Content | 0.02 | 0.02 | 0.02 | 0.02 | 0.02 | 0.02 |
| | Additive | Type | B-3/ | B-1 | B-1 | B-5 | B-1 | B-2/ |
| | | | B-4 | | | | | B-4 |
| | | | (95/5) | | | | | 50/50) |
| | | Contest | 0.1 | 0.1 | 0.1 | 0.1 | 0.1 | 0.1 |
| | | Type | PGMEA | PGME/GBL | PGMEA | PGMEA | PGMEA | PGMEA |
| | | | | (90/10) | | | | |
| | | Content | 77.977 | 79.88 | 79.88 | 79.88 | 79.88 | 79.9794 |
| | Concentration of solid | | 22.023 | 20.12 | 20.12 | 20.12 | 20.12 | 20.0206 |
| | contents | | | | | | | |
| First filtering step | | Filter | No. 2 | No. 2 | No. 131 | No. 2 | No. 101 | No. 2 |
| | | [symbol] | 47.2 | 47.2 | 47.2 | 47.2 | 47.2 | 47.2 |
| Precursor | Resin | Type | P-25 | P-26 | P-27 | P-28 | P-29 | P-30 |
| composition 2 | | Content | 0.3 | 0.3 | 0.3 | 0.3 | 0.3 | 0.3 |
| | Polymerization | Type | A-1 | A-2 | A-1 | A-6 | A-8 | A-1 |
| | inhibitor | Content | 0.0003 | 0.0003 | 0.0003 | 0.0003 | 0.0003 | 0.0003 |
| | Additive | Type | B-3/B-4 | B-1 | B-1 | B-5 | B-1 | B-2/B-4 |
| | | | (95/5) | | | | | (50/50) |
| | | Content | 0.00015 | 0.0015 | 0.0015 | 0.0015 | 0.0015 | 0.0015 |
| | Solvent | Type | PGMEA | PGME/GBL | PGMEA | PGMEA | PGMEA | PGMEA |
| | | | | (98/10) | | | | |
| | | Content | 99.6982 | 99.6982 | 99.6982 | 99.6982 | 99.6982 | 99.6982 |

| | | | | | | |
|---|---|---|---|---|---|---|
| Concentration of sold. | 0.3018 | 0.3018 | 0.3018 | 0.3018 | 0.3018 | 0.3018 |
| contents | | | | | | |

| | | | | | | | |
|---|---|---|---|---|---|---|---|
| Second filtering step | Filter | Purasol ™ | IonKleen ™ | Purasol ™ | Purasol ™ | [symbol] | IonKleen ™ |
| | | SP | SL | SP | SN | P-Nylon | AQ |
| | [symbol] | 8.8 | 8.8 | 8.8 | 8.8 | 8.8 | 8.8 |

| | | | | | | |
|---|---|---|---|---|---|---|
| Adhesiveness | A | A | A | A | A | A |
| Damage to mold | A | A | A | A | A | A |
| Adhesiveness after aging | A | A | A | A | A | A |

[symbol]

indicates data missing or illegible when filed

TABLE 4

| | | | Example |
|---|---|---|---|
| | | | 36 |
| Precursor | Resin | Type | P-1 |
| composition 1 | | Content | 20 |
| | Polymerization | Type | A-1 |
| | inhibitor | Content | 0.02 |
| | Additive | Type | B-1/B-2 |
| | | | (90/10) |
| | | Content | 0.1 |
| | Solvent | Type | PGMEA |
| | | Content | 79.88 |
| | Concentration of solid contents | | 20.12 |
| First filtering step | | Filter | No. 2 |
| | | cm/min | 47.2 |
| Precursor | Resin | Type | P-1 |
| composition 2 | | Content | 0.3 |
| | Polymerization | Type | A-1 |
| | inhibitor | Content | 0.0003 |
| | Additive | Type | B-1/B-2 |
| | | | (90/10) |
| | | Content | 0.0015 |
| | Solvent | Type | PGMEA |
| | | Content | 99.6982 |
| | Concentration of solid contents | | 0.3018 |
| Second filtering step | | Filter | Purasol ™ SP |
| | | cm/min | 8.8 |
| Precursor | Resin | Type | P-1 |
| composition 3 | | Content | 0.3 |
| | Polymerization | Type | A-1 |
| | inhibitor | Content | 0.0003 |
| | Additive | Type | B-1/B-2 |
| | | | (90/10) |
| | | Content | 0.0015 |
| | Solvent | Type | PGMEA |
| | | Content | 99.6982 |

| | |
|---|---|
| Concentration of solid contents | 0.3018 |

| Third filtering step | Filter | PE-Kleen |
|---|---|---|
| | cm/min | 8.8 |

| | |
|---|---|
| Adhesiveness | A |
| Damage to mold | A |
| Adhesiveness after aging | A |

Details of each of the components listed in the tables are as follows.

[Resin]

P-1 to P-31: polymer compounds consisting of repeating units having the following structures; * represents a bonding site with other repeating units; parenthesized subscript described in a main chain represents a content molar ratio of each repeating unit, and details of a, b, and c are shown in the tables; parenthesized subscript described in a side chain represents an arithmetic mean value of the repetition numbers of each repeating unit; weight-average

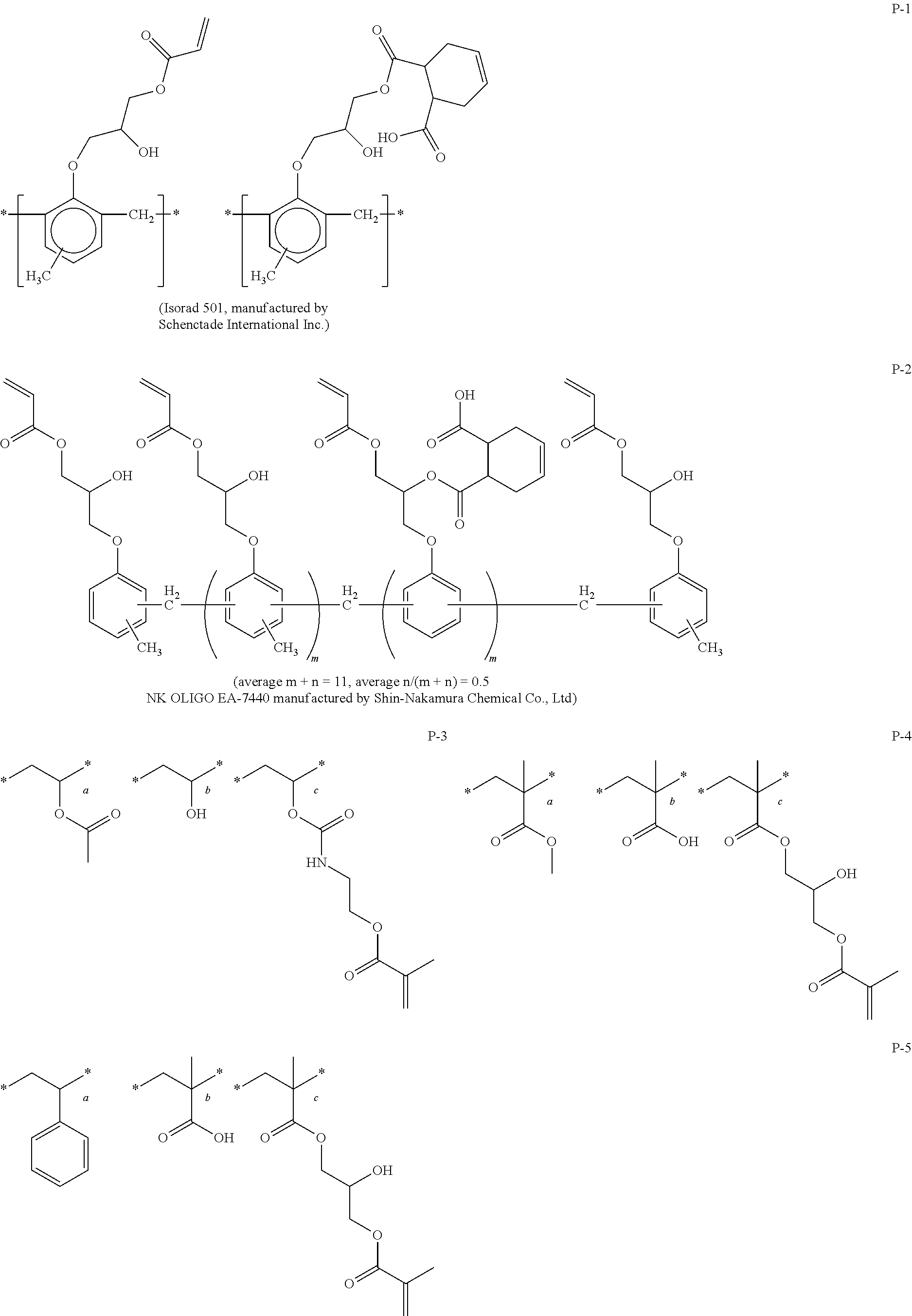

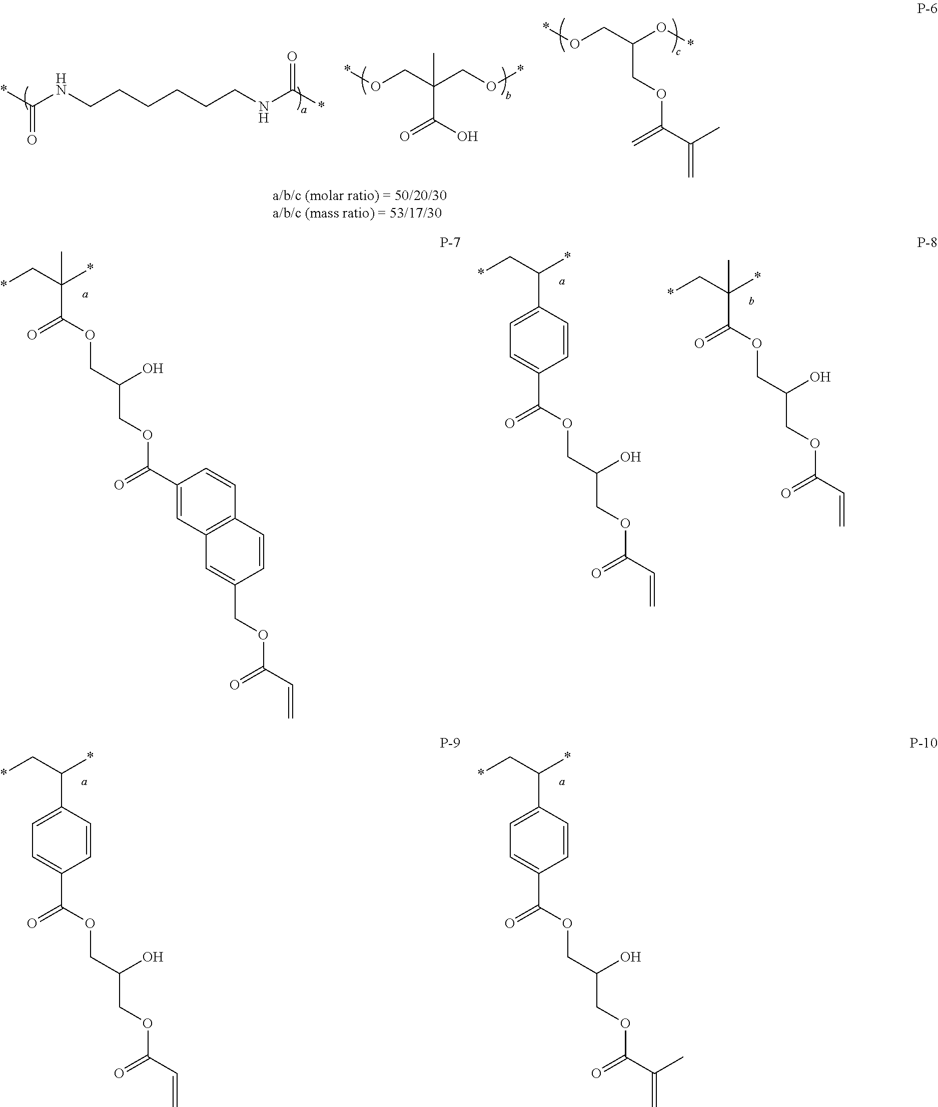

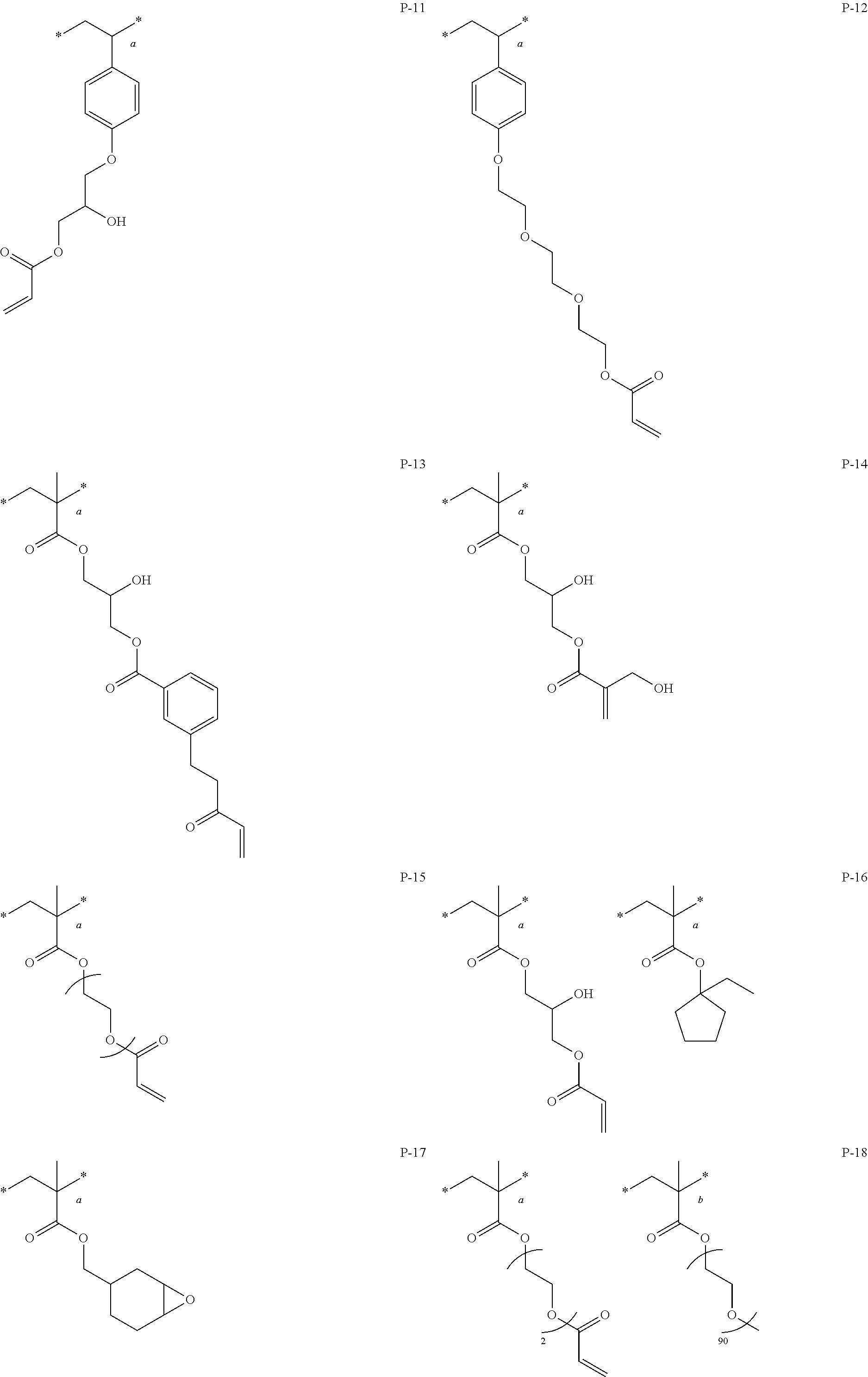

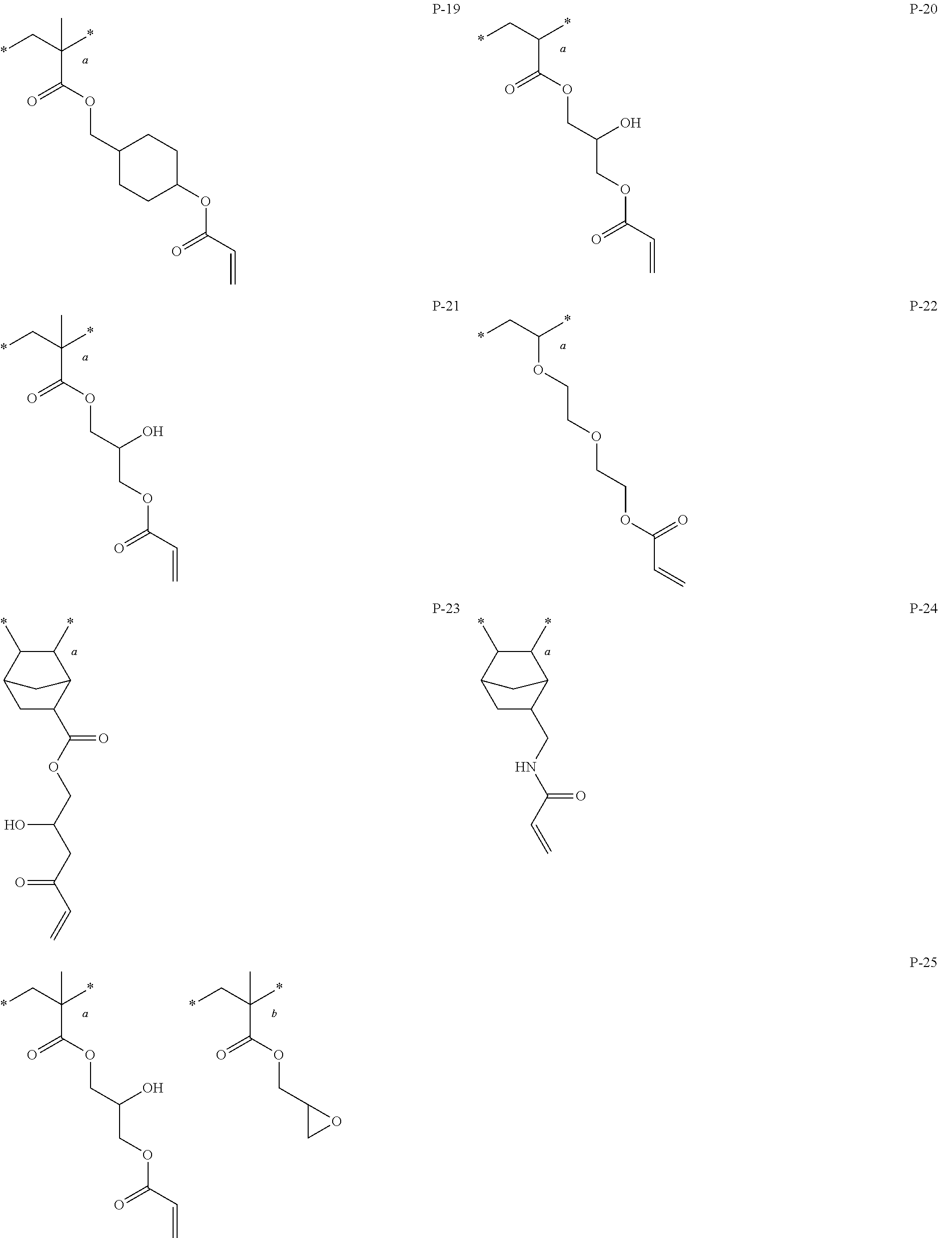

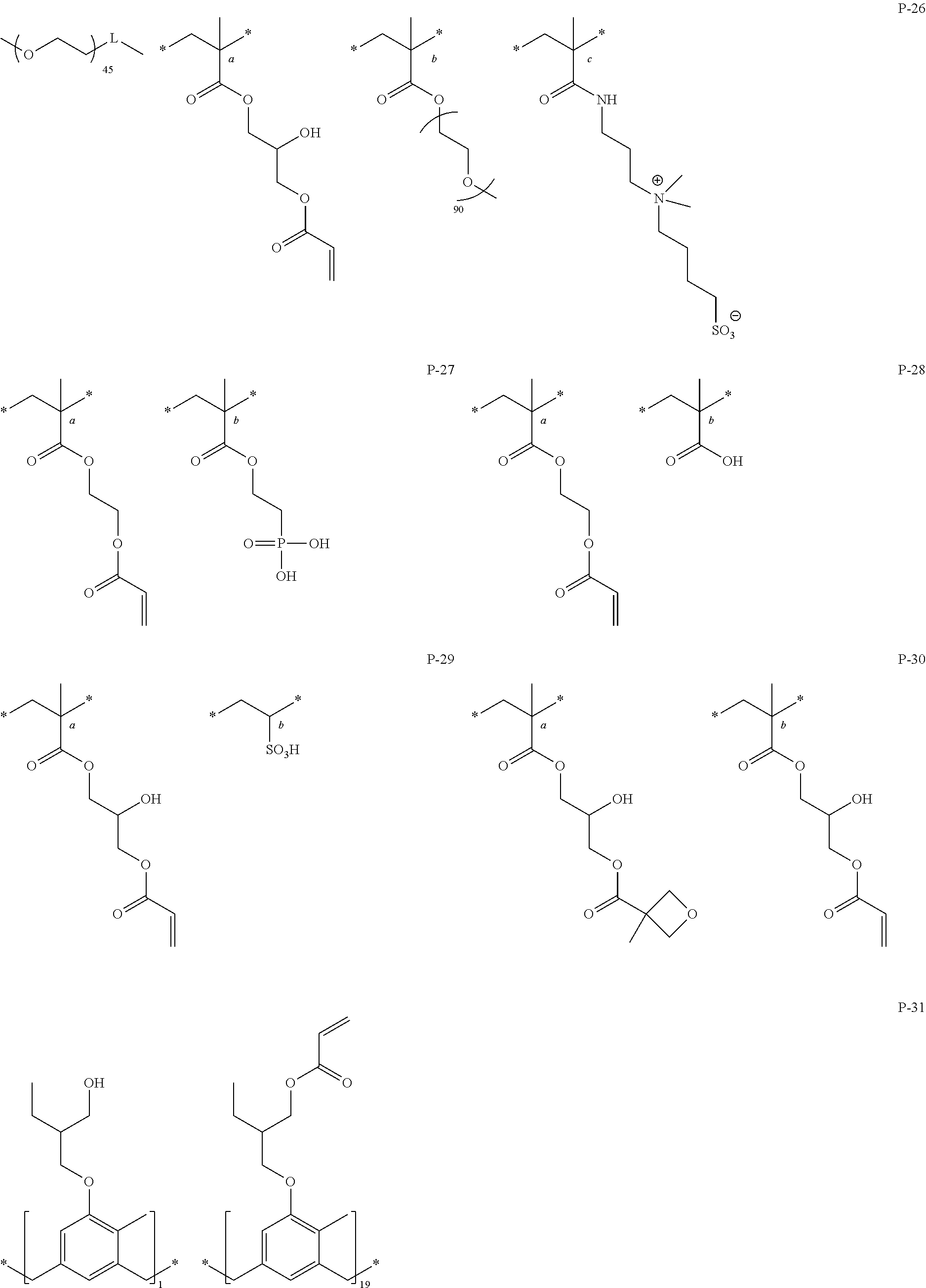

In P-26 described above, L is a structure derived from the following initiator.

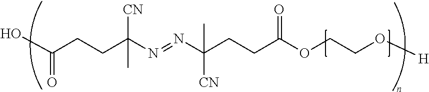

TABLE 5

| Resin | Weight-average molecular weight | a | b | c |
|---|---|---|---|---|
| P-2 | 4000 | — | — | — |
| P-3 | 20000 | 20 | 10 | 70 |
| P-4 | 15000 | 35 | 5 | 60 |
| P-5 | 20000 | 10 | 1 | 89 |
| P-6 | 40000 | 50 | 20 | 30 |
| P-7 | 20000 | 100 | — | — |
| P-8 | 50000 | 50 | 50 | — |
| P-9 | 20000 | 100 | — | — |
| P-10 | 20000 | 100 | — | — |
| p-11 | 20000 | 100 | — | — |
| P-12 | 10000 | 100 | — | — |
| P-13 | 30000 | 100 | — | — |
| P-14 | 6000 | 100 | — | — |
| P-15 | 20000 | 100 | — | — |
| P-16 | 35000 | 50 | 50 | — |
| P-17 | 20000 | 100 | — | — |
| P-18 | 50000 | 90 | 10 | — |
| P-19 | 20000 | 100 | — | — |
| P-20 | 20000 | 100 | — | — |
| P-21 | 20000 | 100 | — | — |
| P-22 | 20000 | 100 | — | — |
| P-23 | 20000 | 100 | — | — |
| P-24 | 20000 | 100 | — | — |
| P-25 | 110000 | 40 | 60 | — |
| P-26 | 75000 | 85 | 10 | 5 |
| P-27 | 20000 | 95 | 5 | — |
| P-28 | 5000 | 70 | 30 | — |
| P-29 | 20000 | 95 | 5 | — |
| P-30 | 20000 | 60 | 40 | — |

[Polymerization Inhibitor]
A-1: 4-methoxyphenol
A-2: 2,2-diphenyl-1-picrylhydrazyl
A-3: poly(4-methacryloyloxy-2,2,6,6-tetramethylpiperidin-N-oxyl)
A-4: 4-tert-butylcatechol
A-5: 1,4-benzoquinone
A-6: phenothiazine
A-7: N,N-diethylhydroxylamine
A-8: 4-hydroxy-2,2,6,6-tetramethylpiperidine 1-oxyl
A-9: Cupferron
A-10: 2,4-bis(octylthiomethyl)-6-methylphenol
A-11: triphenyl phthalazinyl
A-12: pentaerythritol tetrakis[3-(3,5-di-tert-butyl-4-hydroxyphenyl)propionate]
A-13: 2,2,6,6-tetramethylpiperidine 1-oxyl
A-14: tris(2,4-di-tert-butylphenyl) phosphite
A-15: dioctadecyl 3,3′-thiodipropionate

[Additive]
B-1: CYMEL 303 ULF (manufactured by Allnex GMBH)
B-2: K-PURE TAG-2678 (manufactured by King Industries, Inc.)
B-3: dipentaerythritol hexaacrylate
B-4: phenylbis(2,4,6-trimethylbenzoyl)phosphine oxide
B-5: (2-ethylhexanoyl)(tert-butyl)peroxide

[Solvent]
PGMEA: propylene glycol monomethyl ether acetate
PGME: propylene glycol monomethyl ether
GBL: γ-butyrolactone

[Filter]
No. 2: qualitative filter paper manufactured by ADVANTEC Co., Ltd., No. 2
Purasol™ SP: Purasol™ SP manufactured by Entegris
No. 4A: qualitative filter paper manufactured by ADVANTEC Co., Ltd., No. 4A
No. 1: No. 1 (qualitative filter paper manufactured by ADVANTEC Co., Ltd.)
No. 131: qualitative filter paper manufactured by ADVANTEC Co., Ltd., No. 131
No. 101: qualitative filter paper manufactured by ADVANTEC Co., Ltd., No. 101
LifeASSURE™: manufactured by 3M Company, LifeASSURE™
P Emflon: manufactured by Nihon Pall Corporation, P Emflon
Purasol™ SN: Purasol™ SN manufactured by Entegris
Protego Plus LT: Protego Plus LT manufactured by Entegris
IonKleen™ SL: manufactured by Nihon Pall Corporation, IonKleen™ SL
IonKleen™ AN: manufactured by Nihon Pall Corporation, IonKleen™ AN
PE-Kleen: manufactured by Nihon Pall Corporation, PE-Kleen
Ultipor N66: manufactured by Nihon Pall Corporation, Ultipor N66
Ultipleat P-Nylon: manufactured by Nihon Pall Corporation, Ultipleat P-Nylon
IonKleen™ AQ:manufactured by Nihon Pall Corporation

<Evaluation>

[Evaluation of Adhesiveness]

—Preparation of Composition for Forming Pattern—

Compounds shown in the table below were formulated in a formulation proportion (part by mass) shown in the table below, and 4-hydroxy-2,2,6,6-tetramethylpiperidine-1-oxyl free radical (manufactured by Tokyo Chemical Industry Co., Ltd.) as a polymerization inhibitor was further added thereto so that an amount thereof was 100 ppm by mass (0.01% by mass) with respect to an amount of the polymerizable compound (in compositions V-1 and V-2 for forming a pattern, the total amount of No. 1 to No. 3 in the table, and in a composition V-3 for forming a pattern, an amount of No. 1), thereby preparing compositions V-1 to V-3 for forming a pattern. The mixture was filtered with a nylon filter having a pore diameter of 0.02 μm and an UPE filter having a pore diameter of 0.001 μm to prepare the compositions V-1 to V-3 for forming a pattern. In the table, k+m+n is 10.

TABLE 6

| | Composition V-1 for forming pattern | |
|---|---|---|
| | | Formulating |
| | | amount (part |
| No. | Compound | by mass) |
| 1 | 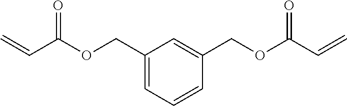 [SMILES: C=CC(=O)OCc1cccc(COC(=O)C=C)c1] | 65 |
| 2 | 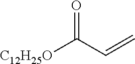 | 20 |
| 3 | 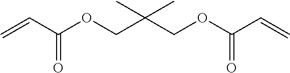 | 15 |
| 4 | 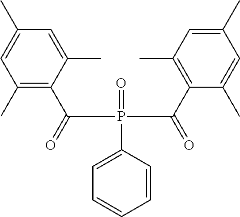 [SMILES: Cc1cc(C)c(C(=O)P(=O)(C(=O)c2c(C)cc(C)cc2C)c2ccccc2)c(C)c1] | 2 |
| 5 | 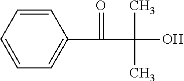 | 2 |
| 6 | 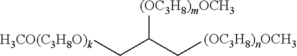 | 3 |
| | Composition V-2 for forming pattern | |
| | | Formulating |
| | | amount (part |
| No. | Compound | by mass) |
| 1 | 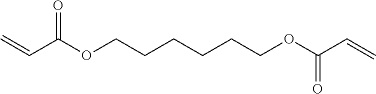 [SMILES: C=CC(=O)OCCCCCCOC(=O)C=C] | 50 |
| 2 | 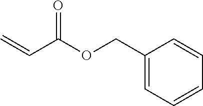 | 40 |
| 3 | 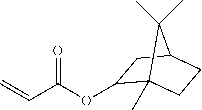 | 10 |
| 4 | 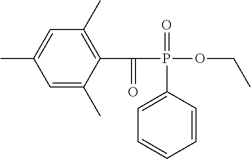 [SMILES: CCOP(=O)(C(=O)c1c(C)cc(C)cc1C)c1ccccc1] | 1 |
| 5 | 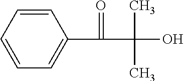 | 2 |
| 6 | Fluorine-based surfactant | 2 |
| | Capstone FS-3100 | |
| | (manufactured by DuPont) | |
| | Composition V-3 for forming pattern | |
| | | Formulating |
| | | amount (part |
| No. | Compound | by mass) |
| 1 | | 24 |
| 2 | 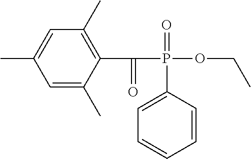 [SMILES: CCOP(=O)(C(=O)c1c(C)cc(C)cc1C)c1ccccc1] | 2 |
| 3 | 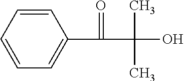 | 1 |
| 4 | Fluorine-based surfactant | 2 |
| | Capstone FS-3100 | |
| | (manufactured by DuPont) | |
| 5 | PGMEA | 70 |

[Synthesis of Silicone Polymer 1]

A silicone resin X-40-9225 (trade name, manufactured by Shin-Etsu Chemical Co., Ltd.) (10 parts), 2-hydroxyethyl acrylate (58.1 parts), and paratoluene sulfonic acid monohydrate (0.034 parts) were mixed with each other, and then the mixture was heated at 120° C. and stirred for 3 hours while distilling off methanol produced by a condensation reaction to obtain 48 parts of a silicone polymer 1.

In each of Examples or Comparative Examples, the prepared composition for forming an interlayer for nanoimprint or comparative composition was spin-coated on a silicon wafer, and was heated for 1 minute using a hot plate at 250° C. to form an interlayer (interlayer for nanoimprint) having a thickness of 5 nm.

Moreover, the above-described composition V-1 for forming a pattern was applied to the above-described interlayer using an ink jet device (INK JET PRINTER DMP-2831 manufactured by FUJIFILM Dimatix Inc.) to form a curable layer. The thickness of the curable layer was 50 nm. An ejected amount from the ink jet device was 1 pL per nozzle. Thereafter, a mold for imprinting was pressed against the silicon wafer from the side of the above-described curable layer under a helium atmosphere. The used mold for imprinting was a quartz mold with line/space having a line width of 15 nm, a depth of 40 nm, and a pitch of 30 nm.

Thereafter, while the above-described mold for imprinting was pressed against the silicon wafer, exposure was performed from a side of the mold for imprinting through the mold for imprinting using an ultra-high pressure mercury lamp under the following two conditions, a condition A and a condition B, and the mold was released to obtain a pattern consisting of the cured substance of the composition for forming a pattern.

TABLE 7

| | Illuminance at each wavelength [mW/cm²] | | | Exposure |
|---|---|---|---|---|
| | 313 nm | 365 nm | 405 nm | time (sec) |
| Condition A | 500 | 680 | 570 | 0.2 |
| Condition B | 1000 | 1350 | 1150 | 0.1 |

The transferred pattern was observed by optical microscope observation (macro-observation) and scanning electron microscope observation (micro-observation), and based on the following standard, the presence or absence of pattern peeling was confirmed. The evaluation results are described in the column of “Adhesiveness” of the tables. It can be said that the adhesiveness is excellent as the pattern peeling is not observed.

—Evaluation Standard—

S: pattern peeling was not observed in any of the observations.

A: in the macro-observation, pattern peeling was not observed, but in the micro-observation, pattern peeling was observed.

B: In the macro-observation, peeling was observed in some regions (release end part).

C: in the macro-observation, peeling was observed in multiple regions (release end part).

[Damage to Mold]

The surface of the released mold was observed by optical microscope observation (macro-observation) and scanning electron microscope observation (micro-observation), and based on the following standard, the presence or absence of damage to the mold was confirmed. The evaluation results are described in the column of “Damage to mold” of the tables. It can be said that the releasability is excellent as a damaged part is not observed.

—Evaluation Standard—

A: damage to the mold was not observed in any of the observations.

B: in the macro-observation, damage to the mold was not observed, but in the micro-observation, damage to the mold was observed.

C: in the macro-observation, damage to the mold was observed in multiple regions (release end part).

[Adhesiveness after Aging]

A composition for forming an interlayer for nanoimprint was prepared in the same manner as in each of Examples or Comparative Examples, except that the precursor 1 after the first filtration was stored under conditions of 25° C. and 1 atm for 7 days, and evaluation was performed by the same method and the same evaluation standard as in the evaluation of the adhesiveness described above.

The evaluation results are described in the column of “Adhesiveness after aging” of the tables.

Moreover, in each of Examples or Comparative Examples, even in a case where the adhesiveness, the damage to the mold, and the adhesiveness after aging were evaluated by the same method as described above, except that the above-described composition V-1 for forming a pattern was changed to the composition V-2 for forming a pattern, the evaluation results in each of Examples or Comparative Examples were the same.

Further, in each of Examples or Comparative Examples, even in a case where the adhesiveness, the damage to the mold, and the adhesiveness after aging were evaluated by the same method as described above, except that the above-described composition V-1 for forming a pattern was changed to the composition V-3 for forming a pattern, and instead of forming the curable layer using the ink jet device, the above-described composition V-3 for forming a pattern was applied by a spin coating method and then heated and dried at 60° C. for 5 minutes to form a curable layer having a thickness of 80 nm, the evaluation results in each of Examples or Comparative Examples were the same.

In each of Examples or Comparative Examples, even in a case where the adhesiveness, the damage to the mold, and the adhesiveness after aging were evaluated by the same method as described above, except that the base material was changed to a spin on carbon base material or a spin on glass base material, the evaluation results in each of Examples or Comparative Examples were the same.

From the above results, it can be seen that, in a case where the interlayer was formed by using the method for producing a composition for forming an interlayer for nanoimprint according to the embodiment of the present invention, the adhesiveness was excellent.

In the production method according to Comparative Example 1, the first filtering step was not performed. In a case of using the composition obtained by such a production method, it is found that the pattern defects were generated in the curable layer formed on the interlayer.

Moreover, using the composition for forming an interlayer for nanoimprint, obtained by the method for producing a composition for forming an interlayer for nanoimprint according to each Example, an interlayer was formed on a silicon wafer, and a line & space structure, a contact hole structure, a dual damascene structure, or a staircase structure was formed on the silicon wafer with the interlayer using a composition for forming a pattern. In addition, each silicon wafer was dry-etched by using this pattern as an etching mask, and each semiconductor element was manufactured using this silicon wafer. There was no problem with the performance of any of the semiconductor elements. Further, using the composition for forming an interlayer and the composition for forming a pattern of Example 1, a semiconductor element was manufactured on a substrate having a spin-on carbon (SOC) layer by the same procedure as described above. There was no problem with the performance of this semiconductor element as well.

What is claimed is:

1. A method for producing a composition for forming an interlayer for nanoimprint, which is used for forming an interlayer existing between a base material and a curable layer, the method comprising:
a first filtering step of filtering a precursor composition 1 including a resin having a polymerizable group with a filter;
a preparing step of adding a solvent to the precursor composition 1 after the first filtering step to obtain a precursor composition 2; and
a second filtering step of filtering the precursor composition 2 with a filter,
wherein a proportion of a total solid content of the obtained composition for forming an interlayer for nanoimprint to a total mass of the obtained composition for forming an interlayer for nanoimprint is 0.1% to 1.0% by mass.

2. The method for producing a composition for forming an interlayer for nanoimprint according to claim 1,
wherein a concentration of solid contents of the precursor composition 1 subjected to the first filtering step is greater than 1.0% by mass, and
a concentration of solid contents of the precursor composition 2 subjected to the second filtering step is 1.0% by mass or lower.

3. The method for producing a composition for forming an interlayer for nanoimprint according to claim 1,
wherein a pore diameter of the filter used in the second filtering step is smaller than a pore diameter of the filter used in the first filtering step.

4. The method for producing a composition for forming an interlayer for nanoimprint according to claim 1,
wherein a filtration speed in a case where the precursor composition 1 passes through the filter in the first filtering step is 1.0 to 100.0 cm/min.

5. The method for producing a composition for forming an interlayer for nanoimprint according to claim 1,
wherein at least one filter used in the second filtering step is polyethylene, polypropylene, nylon, or polytetrafluoroethylene.

6. The method for producing a composition for forming an interlayer for nanoimprint according to claim 1,
wherein a content of a polymerization inhibitor is 0.01 mass % or lower with respect to the total mass of the composition for forming an interlayer for nanoimprint.

7. A method for producing a laminate, the method comprising:
a step of applying, onto a base material, the composition for forming an interlayer for nanoimprint, which is obtained by the method for producing a composition for forming an interlayer for nanoimprint according to claim 1.

8. An imprint pattern producing method comprising:
a curable layer-forming step of applying a composition for forming a pattern onto a member to be applied, which is selected from the group consisting of a laminate obtained by the method for producing a laminate according to claim 7 and a mold;
a contact step of contacting a member which is not selected as the member to be applied from the group consisting of the laminate and the mold with the composition for forming a pattern as a contact member;
a curing step of forming the composition for forming a pattern into a cured substance; and
a peeling step of peeling off the mold from the cured substance.

9. A method for manufacturing a device, comprising:
the imprint pattern producing method according to claim 8.
